(19) United States
(12) Patent Application Publication
(10) Pub. No.: US 2005/0100760 A1
(43) Pub. Date: May 12, 2005

(54) White organic electroluminescent device

(75) Inventor: Meiso Yokoyama, Saitama (JP)

Correspondence Address: GREENBLUM & BERNSTEIN, P.L.C., 1950 ROLAND CLARKE PLACE, RESTON, VA, 20191, US

(73) Assignees: PENTAX Corporation, Tokyo (JP); ITC INC., LTD, Saitama (JP)

(21) Appl. No.: 10/970,002

(22) Filed: Oct. 22, 2004

(30) Foreign Application Priority Data
Oct. 24, 2003 (JP) P2003-364482
Jun. 25, 2004 (JP) P2004-188445

(51) Int. Cl. H05B 33/14

(52) U.S. Cl. 428/690; 428/917; 313/504; 313/506

(57) ABSTRACT

A white organic EL device has an organic layer between an anode and a cathode on a substrate. The organic layer has at least a blue emitting layer, a red emitting layer, and a green emitting layer. The red emitting layer contains a blue emitting compound doped with at least one of a yellow dopant dye 14b and a red dopant dye 14c. When a voltage is applied between the anode and the cathode, each emitting layer emits blue, red, and green light respectively, therefore the white organic EL device 20 emits white light.

### BACKGROUND OF THE INVENTION

1. Field of the Invention

The present invention is in relation to an organic electroluminescent device which emits white light.

2. Description of the Related Art

Conventionally, several methods for displaying full color images using an organic electroluminescent device are known. In one of these methods, a white organic electroluminescent device (hereafter “white organic EL device”) emits white light, then the white light is filtered by an RGB color filter so as to obtain Red, Green, and Blue colored light.

The white organic EL device, which is used in the above method, is disclosed in Japanese patent NO. 3451680 for example. This reference discloses a white organic EL device that has an emitting layer which is composed of a blue emitting layer, a green emitting layer, and red emitting layer. In this reference, the blue emitting layer consists of the green emitting compound doped with a red dopant dye. When the voltage is applied to the white organic EL device, each emitting layer emits light of its respective color. Due to this, the white organic EL device can emit white light.

These white organic EL devices are expected to be used in many fields, for example television displays, digital camera displays, and so on. If they are used as displays, the luminous intensity needs to be adjusted.

However, in the white organic EL devices disclosed in that reference, if the voltage applied to the device is changed in order to adjust the luminous intensity, the chromaticity of the light from the EL device is changed as well. Namely, the color balance of the white light from the EL devices disclosed in that reference, changes depending on the applied voltage.

### SUMMARY OF THE INVENTION

Therefore, an object of the present invention is to provide a white organic EL device, which can emit white light having high color purity. Another object of the present invention is to provide a white organic EL device, which can emit white light having a color balance that does not change depending on a voltage applied to the EL device.

According to the present invention, there is provided an organic electroluminescent device, emitting white light, comprising an organic layer between an anode and a cathode on a substrate (ITO coated glass). The organic layer has at least a first blue emitting layer for emitting blue light, a first green emitting layer for emitting green light, and a red emitting layer for emitting red light. The red emitting layer contains a blue emitting compound doped with at least one of a yellow dopant dye and a red dopant dye.

Preferably, the blue emitting compound is a hole-transporting compound. Preferably, the organic layer has in sequence from the anode, the red emitting layer, the first blue emitting layer, and the first green emitting layer.

If the red emitting layer contains both the yellow dopant dye and the red dopant dye, the content of the yellow dopant dye may be higher than the content of the red dopant dye.

The organic layer can have in sequence from the anode side, the first blue emitting layer, the red emitting layer, and the first green emitting layer.

The organic layer can have a second blue emitting layer between the red emitting layer and the first green emitting layer.

The organic layer can have a second green emitting layer on the anode side of the second blue emitting layer.

Preferably, the organic layer has a hole-injection layer on the side closest to the anode, the hole-injection layer containing CuPc and MTDATA.

According to the present invention, there is provided an organic electroluminescent device, for emitting light, comprising an organic layer emitting the light between an anode and a cathode on a substrate. The organic layer has a hole-injection layer on the closest side to the anode, and the hole-injection layer contains CuPc and MTDATA.

In this case, the hole-injection layer can have a first hole-injection layer containing CuPc and a second hole-injection layer containing MTDATA. Further, the hole-injection layer can contain a mixture of CuPc and MTDATA.

### BRIEF DESCRIPTION OF THE DRAWINGS

The objects and advantages of the present invention will be better understood from the following description, with reference to the accompanying drawings in which:

FIG. 1 is a schematic perspective view showing the organic EL device in a first embodiment of the present invention,

FIG. 2 is a schematic perspective view showing the organic EL device in a second embodiment of the present invention,

FIG. 3 is a schematic perspective view showing the organic EL device in a third embodiment of the present invention,

FIG. 4 is a schematic perspective view showing the organic EL device in a fourth embodiment of the present invention,

FIG. 5 is a schematic perspective view showing the organic EL device in a fifth embodiment of the present invention,

FIG. 6 is a schematic perspective view showing the organic EL device in a sixth embodiment of the present invention,

FIG. 7 is a plot of measured electroluminescence spectrums in Example 1,

FIG. 8 is a diagram of the chromaticity coordinate in Example 1,

FIG. 9 is a plot of measured electroluminescence spectrums in Example 2,

FIG. 10 is a diagram of the chromaticity coordinate in Example 2,

FIG. 11 is a plot of measured electroluminescence spectrums in Example 3,

FIG. 12 is a diagram of the chromaticity coordinate in Example 3,

FIG. 13 is a plot of measured electroluminescence spectrums in Example 4,

FIG. 14 is a diagram of the chromaticity coordinate in Example 4,

FIG. 15 is a plot of measured electroluminescence spectrums in Example 5,

FIG. 16 is a diagram of the chromaticity coordinate in Example 5,

FIG. 17 is a plot of measured electroluminescence spectrums in Example 6,

FIG. 18 is a diagram of the chromaticity coordinate in Example 6,

FIG. 19 is a plot of measured electroluminescence spectrums in Example 7,

FIG. 20 is a diagram of the chromaticity coordinate in Example 7,

FIG. 21 is a plot of measured electroluminescence spectrums in Example 8,

FIG. 22 is a diagram of the chromaticity coordinate in Example 8,

FIG. 23 is a plot of measured electroluminescence spectrums in Example 9,

FIG. 24 is a diagram of the chromaticity coordinate in Example 9,

FIG. 25 is a plot of measured electroluminescence spectrums in Example 10,

FIG. 26 is a plot of measured electroluminescence spectrums in Example 11,

FIG. 27 is a plot of measured electroluminescence spectrums in Comparative example 1,

FIG. 28 is a diagram of the chromaticity coordinate in Example 10,

FIG. 29 is a graph showing the relation between the applied voltage and the current density in Example 10,

FIG. 30 is a graph showing the relations between the applied voltage and the current density in Example 11 and Comparative example 1,

FIG. 31 is a graph showing the relation between the current density and the luminous efficiency in Example 10,

FIG. 32 is a graph showing the relations between the current density and the luminous efficiency in Example 11 and Comparative example 1,

FIG. 33 is a plot of measured electroluminescence spectrums in Examples 12, 13, and 14,

FIG. 34 is a graph showing the relations between the current density and the luminance levels in Example 12, 13, and 14, and

FIG. 35 is a graph showing the relations between the current density and the luminous efficiency in Example 12, 13, and 15.

### DESCRIPTION OF THE PREFERRED EMBODIMENTS

The present invention will be described below with reference to the embodiments shown in the drawings.

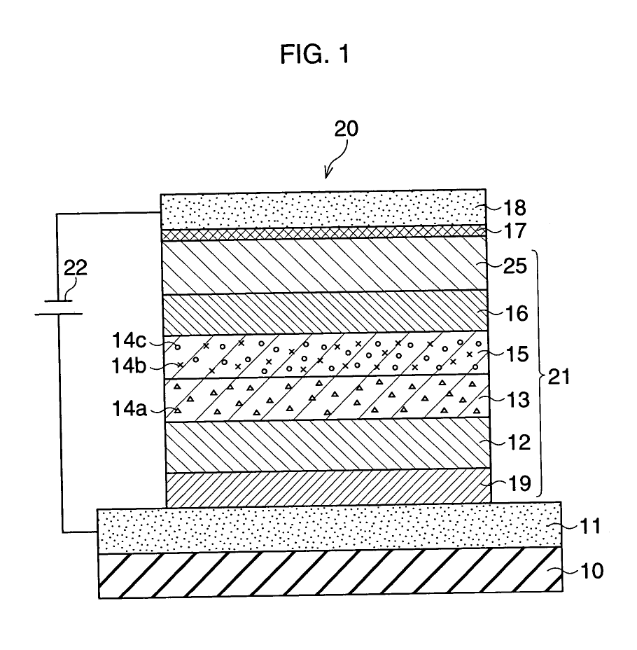

FIG. 1 shows a white organic EL device, to which a first embodiment of the present invention is applied. The white organic EL device 20 has a base member (substrate) 10, an anode 11 which is laid on the base member 10, an organic layer 21 which is laid on the anode 11, an electron injection layer 17 which is laid on the organic layer 21, and a cathode 18 which is laid on the electron injection layer 17.

The base member (substrate) 10 is formed of a glass material having light transmitting properties. The anode 11 is a translucent layer which contains ITO (indium tin oxide). The thickness of the anode 11 is about 100 nm. The organic layer 21, located on the anode 11, emits white light as described below. The white light is sent out of the EL device 20 through the anode 11 and the base member 10.

The organic layer 21 has in sequence from the anode 11 side, a hole-injection layer 19, a hole-transporting layer 12, a blue emitting layer 13, a red emitting layer 15, a green emitting layer 16, and an electron-transporting layer 25. Each layer is closely stacked on an adjoined layer. At least one of the hole-injection layer 19 and the electron-transporting layer 25 can be omitted.

The hole-injection layer 19 contains MTDATA (4,4′,4″-tris(3-methyl-phenyl-phenyl-amino)triphenylamine) as shown in chemical formula [4]. The thickness of the hole-injection layer 19 is from about 10 nm to about 60 nm, preferably about 15 nm. The hole-injection layer 19 can take the hole injected from the anode 11, in the organic layer 21 effectively. Further, the hole-injection layer 19 can be formed from AlF₃, HfO₃, Ta₂O₅, or CuPc (copper phthalocyanine) as shown in chemical formula [4-2], and can be formed from a mixture of CuPc and MTDATA. In the case where the hole-injection layer 19 is formed from an organic compound such as CuPc, MTDATA, or a mixture of these, the thickness of the hole-injection layer 19 is preferably from about 10 nm to about 80 nm. In the case where the hole-injection layer 19 is formed from a mixture of CuPc and MTDATA, the weight ratio between CuPc and MTDATA is in the range from 1:1 to 1.5:1.

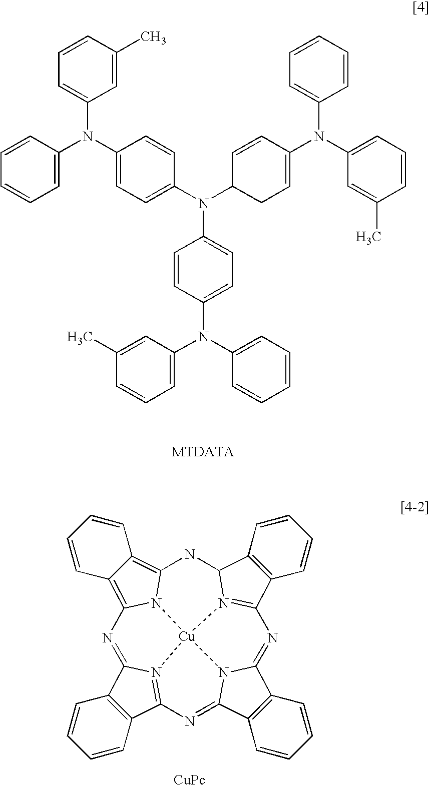

A hole-transporting layer 12 contains a hole-transporting compound which preferably satisfies the structural formula [5]. 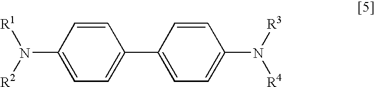
R¹, R², R³, and R⁴ are aryl groups in structural formula [5]. Further, the aryl groups include the alkyl substituted aryl groups in this specification. R¹, R², R³, and R⁴ can be the same aryl group or different aryl groups. Furthermore, the hole-transporting compound preferably satisfies the structural formula of either [6] or [7].

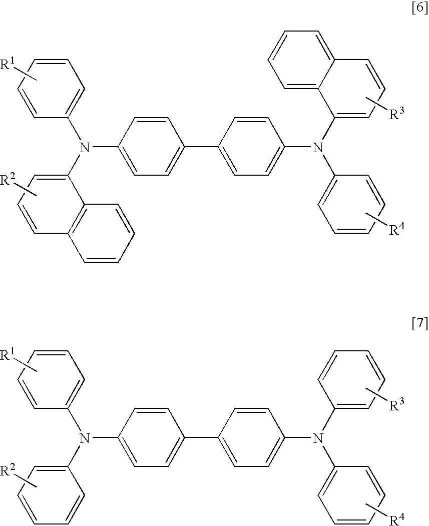

In the structural formula [6] or [7], R¹, R², R³, and R⁴ are hydrogen atoms or alkyl groups having from 1 to 3 carbon atoms. R¹, R², R³, and R⁴ can be the same alkyl group or different alkyl groups. R¹, R², R³, and R⁴ are respectively substituted on optional positions on the benzene or naphthalene skeletons. Specially preferably, the hole-transporting compound is NPB (N,N′-di(naphthalene-1-yl)-N,N′-diphenyl-benzidine) as shown in the chemical formula [8], or TPD (N,N0-diphenyl-N,N0-bis(3-methylphenyl)-1,10-diphenyl-4,40-diamine) as shown in the chemical formula [9]. The hole-transporting layer 12 can contain a mixture of two or more than two kinds of the above described compounds. The thickness of the hole-transporting layer 12 is from about 20 nm to about 100 nm, but is preferably from about 40 nm to about 90 nm. The hole-transporting layer 12 transports the hole, which is injected from the anode 11, to the emitting layers 13, 15, and 16 effectively.

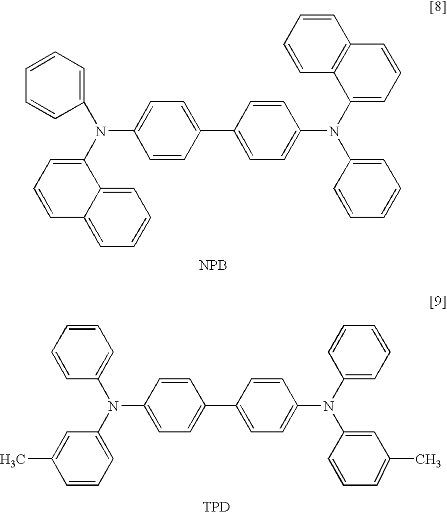

The blue emitting layer 13 contains a blue emitting compound as a host compound and is doped with a blue dopant dye 14a. Namely, the blue emitting layer 13 is formed from the blue emitting compound and the blue dopant dye 14a which is uniformly dispersed into the blue emitting compound. The thickness of the blue emitting layer 13 is from about 10 nm to about 30 nm, and is preferably from about 15 to about 20 nm.

The blue emitting compound of the blue emitting layer 13 is an anthracene derivative or a styryl derivative for example. The styryl derivative preferably satisfies the structural formula [10].

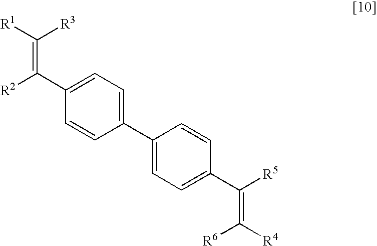

R¹, R², R³, R⁴, R⁵ and R⁶ in the formula [10] are hydrogen atoms or aryl groups (preferably phenyl groups). At least one of R¹, R², and R³ is an aryl group (preferably a phenyl group), and preferably two of R¹, R², and R³ are aryl groups (preferably phenyl groups). At least one of R⁴, R⁵, and R⁶ is an aryl group (preferably a phenyl group) and preferably two of R⁴, R⁵, and R⁶ are aryl groups (preferably phenyl groups) Furthermore, R¹, R², R³, R⁴, R⁵ and R⁶ can be the same aryl groups or different aryl groups.

The styryl derivative is preferably DPVBi (1,4-bis(2,2-diphenylvinyl)biphenyl) as shown in the chemical formula [11] or ADS082 (4,4-bis(diphenylvinylene)-biphenyl) for example. The anthracene derivative is preferably β-ADN (9,10-di(2-naphthyl)anthracene) as shown in the chemical formula [12] or TBADN (2-t-buthyl-9,10-di(2-naphthyl)anthracene) as shown in the structural formula [13] for example. In this embodiment, a mixture of two or more than two kinds of the above described compounds can be used as the blue emitting compound, but preferably DPVBi or ADS082 is only used as the blue emitting compound.

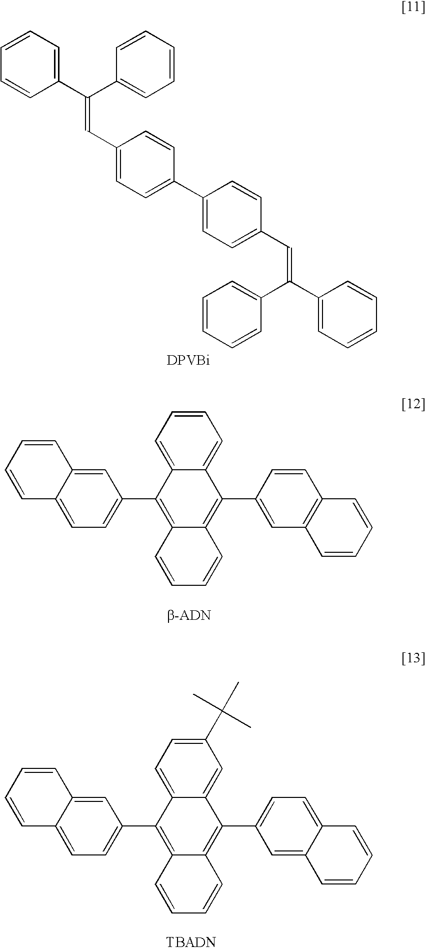

The blue dopant dye 14a is a perylene derivative or Pe (perylene) as shown in the chemical formula [14]. The perylene derivative has a perylene skeleton of which one or more than one alkyl group is substituted on the optional positions. The perylene derivative is preferably TBPe (Tetra(t-butyl)perylene) as shown in the chemical formula [15]. A mixture of two or more than two kinds of those compounds can be used as the blue dopant dye 14a. The blue emitting layer 13 may not be doped with the blue dopant dye 14a. Further, the content of the blue dopant dye 14a, is from 2 to 4 weight percent (preferably 3 weight percent), with respect to the blue emitting compound (the host compound) of the blue emitting layer 13.

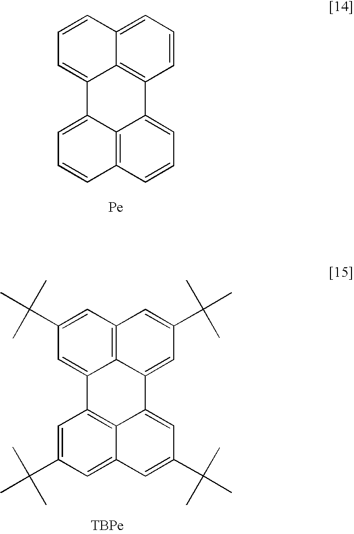

The red emitting layer 15 contains a blue emitting compound as a host compound and is doped with a yellow dopant dye 14b and a red dopant dye 14c. Namely, the red emitting layer 15 is formed from the blue emitting compound and the yellow and red dopant dye 14b and 14c which are dispersed into the blue emitting compound.

The weight content of the yellow dopant dye 14b is higher than the weight content of the red dopant dye 14c in the red emitting layer 15. The weight ratio between the yellow dopant dye 14b and the red dopant dye 14c is in the range from 1.8:1 to 2.2:1, and is preferably about 2:1. The total weight content of the yellow dopant dye 14b and the red dopant dye 14c is from 0.1 to 2 weight percent, and is preferably from 0.1 to 1.5 weight percent, and is more preferably about 1 weight percent with respect to the blue emitting compound of the red emitting layer 15. The thickness of the red emitting layer 15 is preferably from about 5 nm to about 30 nm, and is more preferably from about 10 to about 20 nm.

Further, the red emitting layer 15 does not have to contain both the yellow dopant dye 14b and the red dopant dye 14c. Namely, the emitting layer 15 can contain only one of the yellow dopant dye 14b and the red dopant dye 14c. In this case, the content of the yellow dopant dye 14b or the red dopant dye 14c is from 0.5 to 1.5 weight percent, preferably about 1 weight percent with respect to the blue emitting compound (the host compound) of the red emitting layer 15.

The host compound of the red emitting layer 15 is selected from the blue emitting compounds as described above. Namely, the host compound of the red emitting layer 15 is the styryl derivative or the anthracene derivative for example. The styryl derivative is preferably the compound which satisfies the structural formula [10], and is preferably DPVBi as shown in the chemical formula [11] or ADS082 as described above. The anthracene derivative is preferably β-ADN as shown in the chemical formula [12] or TBADN as shown in the structural formula [13] for example. A mixture of two or more than two kinds of the above described compounds can be used as the host compound of the red emitting layer 15, but preferably either DPVBi or ADS082 only is used as the host compound. More preferably, the host compound of the red emitting layer 15 is the same as the host compound of the blue emitting layer 13.

The yellow dopant dye 14b is a compound having a naphthacene skeleton of which the aryl (for example phenyl) group(s) (preferably from two to six aryl groups) are substituted on the optional positions for example. The yellow dopant dye 14b is a Rubrene as shown in the structural formula [16] for example.

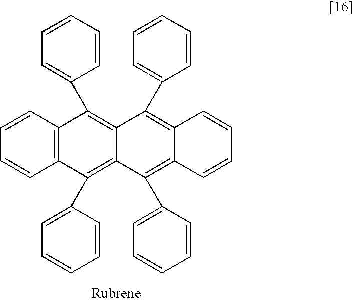

The red dopant dye 14c is a compound satisfying the structural formula [17] for example.

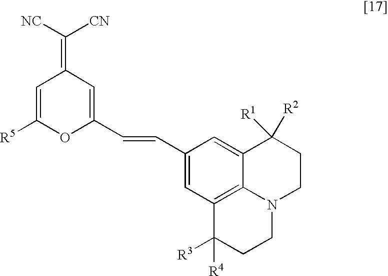

R¹, R², R³, R⁴, and R⁵ in the structural formula [17] are hydrogen atoms or alkyl groups having from 1 to 6 carbon atoms. R¹, R², R³, R⁴, and R⁵ can be same alkyl group or different alkyl groups. The red dopant dye 14c is preferably DCM2 (4-dicyanomethylene-2-methyl-6-(2-(2,3,6,7-tetra-hydro-1H, 5H-benzo) [ij]quinolizin-8-yl)-4H-pyran) as shown in the chemical formula [18] or DCJTB (4-(dicyanomethylene)-2-t-butyl-6-(1,1,7,7-tetramethyljul olidyl-9-enyl)-4H-pyran) as shown in the chemical formula [19] etc. Further, the red dopant dye 14c can be rhodamine 6G as shown in the chemical formula [20] or DCM as shown in the chemical formula [21] etc. Furthermore, a mixture of two or more than two kinds of the above described compounds can be used as the red dopant dye 14c. Preferably, only one of DCJTB and DCM2 is used as the red dopant dye 14c.

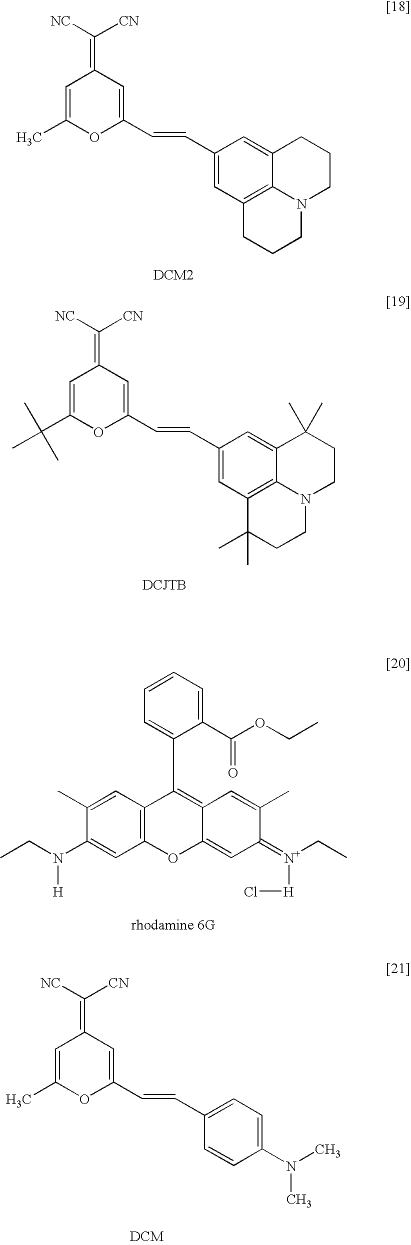

The energy band gap of the yellow dopant dye 14b and the energy band gap of the red dopant dye 14c are smaller than the energy band gap of the blue emitting compound. Further, the energy band gap is the difference between a HOMO (highest occupied molecular orbital) energy level and a LUMO (lowest unoccupied molecular orbital) energy level.

The green emitting layer 16 contains a green emitting compound, which is an alkylate compound, for example and which is preferably Alq₃ (tris-(8-hydroxy-quinoline)aluminum) as shown in the chemical formula [22]. Of course, the green emitting layer 16 can be formed from other organic compounds. Further, the green emitting layer 16 can contain an organic compound (for example Alq₃) which is doped with a green dopant dye. The green dopant dye is coumarin 6 as shown in the chemical formula [23-1] or C545T (10-(1,3-benzothiazol-2-yl)-1,1,7,7-tetramethyl-2,3,6,7-t etrahydro-1H,5H,11H-pyrano[2,3-f]pyrido[3,2,1-ij]quinolin-11-one) as shown in the chemical formula [23-2], etc. The thickness of the green emitting layer 16 is preferably from about 10 nm to about 50 nm, and is more preferably about 25 nm.

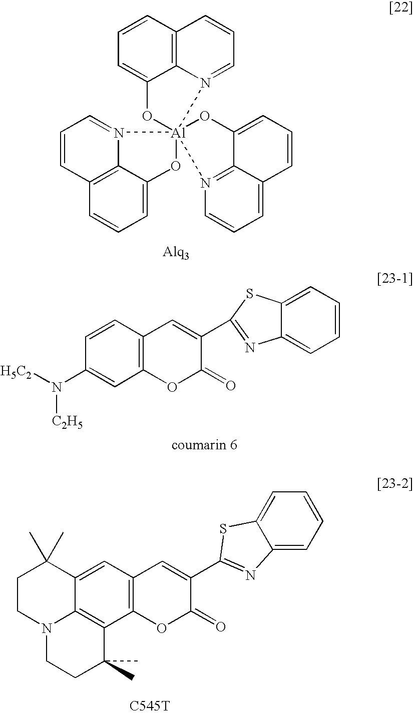

The electron-transporting layer 25 contains the alkylate compound, for example Alq₃, similar to the green emitting layer 16. However, the electron-transporting layer 25 can be formed from other compounds. The thickness of the electron-transporting layer 25 is from about 20 nm to about 30 nm, and is preferably about 25 nm.

The anode 11 and the cathode 18, which the organic layer 21 is inserted between, are connected to a battery 22. The cathode 18 is formed from Aluminum. The electron injection layer 17 is formed between the cathode 18 and the organic layer 21. The electron injection layer 17 can take electrons into the organic layer 21 from the cathode 18 easily. The electron injection layer 17 is formed from Al:Li (aluminum-lithium) or LiF (lithium fluoride). The thickness of the electron injection layer 17 is about 0.7 nm.

Each layer of the anode 11, the organic layer 21, the electron injection layer 17, and the cathode 18 are formed in sequence on the base member 10 by vapor deposition, for example, chemical vapor deposition (CVD) or physical vapor deposition (PVD). Further, the dopant dye and the blue emitting compound (the host compound) are vapor deposited at the same time so as to form the blue emitting layer 13 and the red emitting layer 16.

When the voltage is applied between the anode 11 and the cathode 18 from the battery 22, the holes are injected from the anode 11 and the electrons are injected from the cathode 18. The holes injected from the anode 11 are taken by the hole-injection layer 19, and are then sent to the blue, red, and green emitting layers 13, 15, and 16 by the hole-transporting layer 12. On the other hand, the electrons injected from the cathode 18 are taken by the electron injection layer 17, and are then transported to the blue, red, and green emitting layers 13, 15, and 16 by the electron-transporting layer 25. The holes and electrons are recombined and then to form exciton are in the interface of each of the emitting layers 13, 15, and 16.

These excitons disperse then emit blue light in the blue emitting layer 13. The energy of the excitons in the red emitting layer 15 is transferred to the yellow dopant dye 14b from the blue emitting compound, because the energy level in the excited state of the yellow dopant dye 14b is lower than the energy level in the excited state of the blue emitting compound. And then, the energy in the yellow dopant dye 14b is transferred to the red dopant dye 14c, because the energy level in the excited state of the red dopant dye 14c is lower than the energy level in the excited state of the yellow dopant dye 14b. Due to this, the red light having high color purity is created in the red emitting layer 15. The green light is created in the green emitting layer 16 by the excitons. Blue, red, and green light is created in the respective emitting layers, hence the EL device 20 emits white light. Further, the electron-transporting layer 25 contains the green emitting compound (Alq₃), but the holes and electrons are not recombined in this layer so the electron-transporting layer 25 does not emit light.

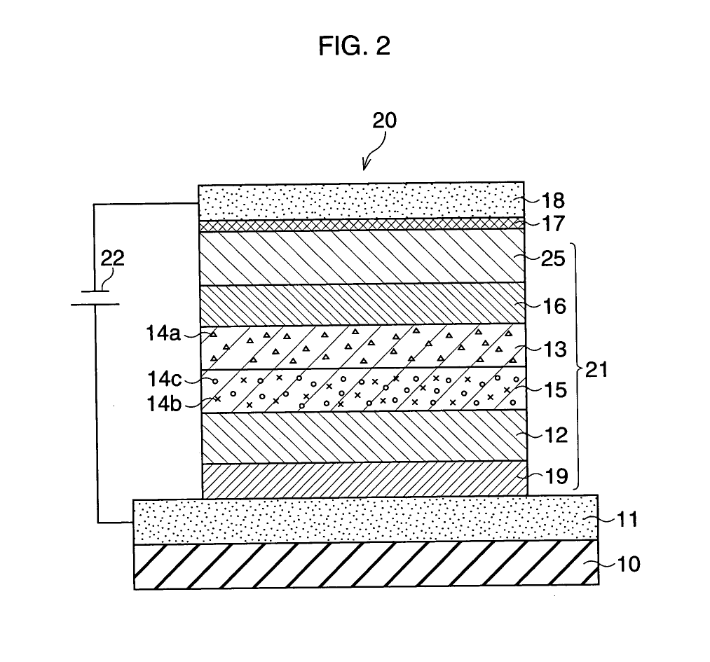

FIG. 2 shows a white organic EL device of the second embodiment. The EL device 20 of the second embodiment has the same structure as that of the first embodiment except for the layer sequence in the organic layer 21.

In the second embodiment, the organic layer 21 has in sequence from the anode 11 side the hole-injection layer 19, the hole-transporting layer 12, the red emitting layer 15, blue emitting layer 13, the green emitting layer 16, and the electron-transporting layer 25. Further, the structure of each layer in the organic layer 21 is the same as that of the first embodiment. Therefore, the explanation of the structure of each layer in the organic layer 21 is omitted.

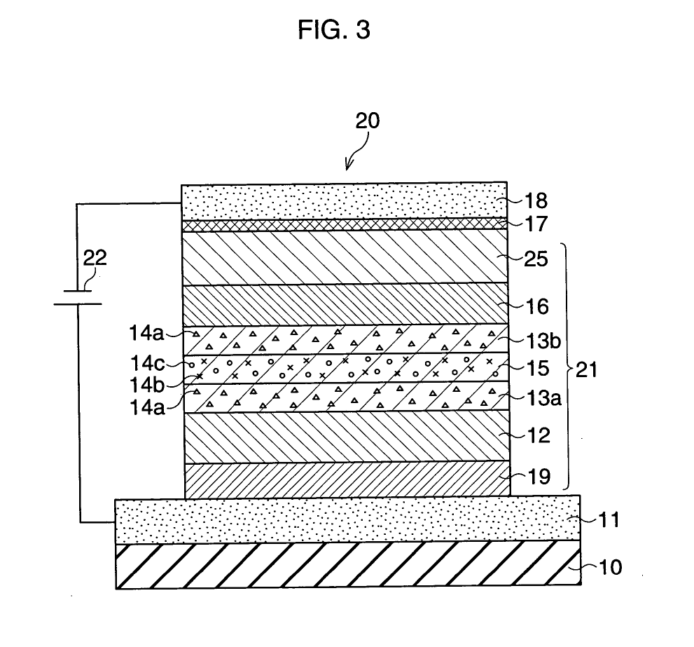

FIG. 3 shows a white organic EL device of the third embodiment. The difference of the third embodiment from the first embodiment is that the organic layer 21 has two blue emitting layers. Namely, the organic layer 21 of the third embodiment has a first blue emitting layer 13a and a second blue emitting layer 13b.

In the third embodiment, the organic layer 21 has in sequence from the anode 11 side the hole-injection layer 19, the hole-transporting layer 12, the first blue emitting layer 13a, the red emitting layer 15, the second blue emitting layer 13b, the green emitting layer 16, and the electron-transporting layer 25.

Both the first blue emitting layer 13a and the second blue emitting layer 13b have the same structure as the blue emitting layer 13 of the first embodiment, therefore the layers 13a and 13b contain the blue emitting compound doped with the blue dopant dye in the same way as the first embodiment. The first and second emitting layer 13a and 13b may contain the same or different blue emitting compounds doped with the same or different blue dopant dye.

In this embodiment, preferably the thicknesses of the first and second emitting layer 13a and 13b are respectively from about 5 nm to about 15 nm. The total thickness of layer 13a, 13b, and 15 is preferably not more than about 50 nm. Other structures of this embodiment are the same as those of the first embodiment and therefore, their explanations are omitted.

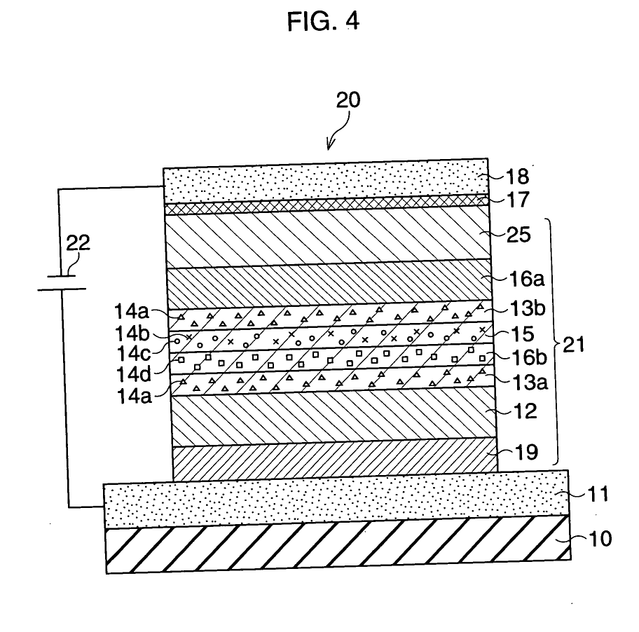

FIG. 4 shows a white organic EL device of the fourth embodiment. The difference of the fourth embodiment from the third embodiment is that the organic layer 21 has a first green emitting layer 16a and a second green emitting layer 16b.

In the fourth embodiment, the organic layer 21 has in sequence from the anode 11 side the hole-injection layer 19, the hole-transporting layer 12, the first blue emitting layer 13a, the second green emitting layer 16b, the red emitting layer 15, the second blue emitting layer 13b, the first green emitting layer 16a, and the electron-transporting layer 25.

The second green emitting layer 16b contains the blue emitting compound as a host compound, and is doped with the green dopant dye 14d. Namely, the second green emitting layer 16b is formed from the blue emitting compound, and the green dopant dye 14d which is dispersed into the blue emitting compound.

The compound which is used as the blue emitting compound of the second green emitting layer 16b is similar to the compound which is used as the blue emitting compound of the blue emitting layers 13 of the first embodiment as described above.

The host compound of the second green emitting layer 16b may be the same as the host compound of the first and/or second blue emitting layers 13a, 13b or may be different from the host compound of the first and/or second blue emitting layer 13a, 13b.

The green dopant dye 14d is coumarin 6 as shown in the chemical formula [23-1] or C545T as shown in the chemical formula [23-2] for example. The structure of the first green emitting layer 16a is the same as the structure of the green emitting layer 16 in the first embodiment.

Preferably, the thicknesses of the first and second blue emitting layers 13a and 13b, the second green emitting layer 16b, and the red emitting layer 15 are respectively from about 5 to about 15 nm each, are more preferably from about 5 to 10 nm. Preferably the total thickness of the layer 13a, 13b, 16b, and 15 is not more than about 50 nm. Further, the other structures in the fourth embodiment are the same as the structures in the third embodiment, therefore the explanations of these are omitted.

Furthermore, the layer sequence of the first blue emitting layer 13a, the second green emitting layer 16b, the red emitting layer 15, and the second blue emitting layer 13b can be changed in fourth embodiment. For example, the organic layer 21 can have in sequence from the anode 11 side the first blue emitting layer 13a, the red emitting layer 15, the second green emitting layer 16b, and the second blue emitting layer 13b.

Further, at least one of the hole-injection layer 19 and the electron-transporting layer 25 can be omitted in the second, third, and the fourth embodiments similar to the first embodiment.

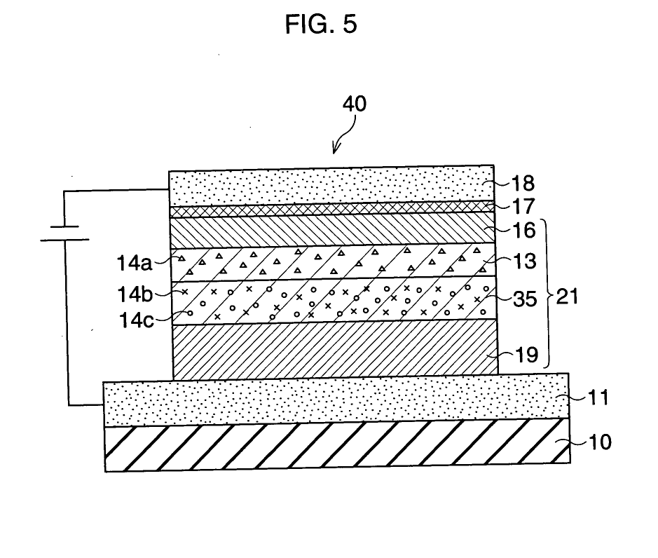

FIG. 5 shows a white organic EL device of the fifth embodiment. The white organic EL device 40 of the fifth embodiment has a base member 10, an anode 11 which is laid on the base member 10, an organic layer 21 which is laid on the anode 11, an electron injection layer 17 which is laid on the organic layer 21, and a cathode 18 which is laid on the electron injection layer 17. The base member 10 and the anode 11 have the same structure of the base member and the anode in the first embodiment. The white light, which the organic layer 21 emits, passes out of the EL device 20 through the anode 11 and the base member 10.

The organic layer 21 has in sequence from the anode 11 side, a hole-injection layer 19, a red emitting layer 35, a blue emitting layer 13, and a green emitting layer 16.

The hole-injection layer 19 contains MTDATA as shown in chemical formula [4] for example, similar to the first embodiment. The hole-injection layer 19 can be formed from AlF₃, HfO₃, Ta₂O₅, or CuPc (copper phthalocyanine) as shown in chemical formula [4-2], and can be formed from a mixture of CuPc and MTDATA. In the case where the hole-injection layer 19 is formed from an inorganic compound such as AlF₃, HfO₃, Ta₂O₅, and so on, the thickness of the hole-injection layer 19 is not more than about 5 nm. In the case where the hole-injection layer 19 is formed from an organic compound such as CuPc, MTDATA, or a mixture of these, the thickness of the hole-injection layer 19 is preferably from about 10 nm to about 80 nm. In the case where the hole-injection layer 19 is formed from a mixture of CuPc and MTDATA, the weight ratio between CuPc and MTDATA is in the range from 1:1 to 1.5:1.

The red emitting layer 35 contains a hole-transporting compound as a host compound and is doped with a yellow dopant dye 14b and a red dopant dye 14c. Namely, the red emitting layer 35 is formed from the hole-transporting compound, and the yellow and red dopant dyes 14b and 14c which are uniformly dispersed into the hole-transporting compound. The peak wavelength of the PL spectrum of the hole-transporting compound in this embodiment may appear in the blue wave range (400-500 nm), therefore the hole-transporting compound may be the blue emitting compound.

The hole-transporting compound used as the host compound in the red emitting layer 35 is a compound which satisfies the structure formula [5] for example and which preferably satisfies one of the structural formula [6] or [7]. The hole-transporting compound is preferably NPB (N,N′-di(naphthalene-1-yl)-N,N′-diphenyl-benzidine) as shown in the chemical formula [8], or TPD (N,N0-diphenyl-N,N0-bis(3-methylphenyl)-1,10-diphenyl-4,40-diamine) as shown in the chemical formula [9]. The red emitting layer 35 can contain a mixture of two or more than two kinds of the above described compounds. However, only one of NPB and TPD is preferably used as the hole-transporting compound of the red emitting layer 35. The thickness of the red emitting layer 35 is from about 20 nm to about 60 nm, and is preferably about 40 nm.

In the red emitting layer 35, the weight content of the yellow dopant dye 14b is higher than the weight content of the red dopant dye 14c in the red emitting layer 35. The weight ratio between the yellow dopant dye 14b and the red dopant dye 14c is in the range from about 1.8:1 to about 2.2:1, and is preferably about 2:1.

The yellow dopant dye 14b is preferably a naphthacene derivative, the same as in the first embodiment. The naphthacene derivative has a naphthacene skeleton of which the aryl (preferably phenyl) group(s) (preferably from two to six aryl groups) are substituted on the optional position(s). The yellow dopant dye 14b is Rubrene as shown in the chemical formula [16] for example. The red dopant dye 14c is preferably a compound which satisfies the chemical formula [17], and is more preferably DCM2 as shown in the chemical formula [18] or DCJTB as shown in the chemical formula [19] for example. However, the red dopant dye 14c can be rhodamine 6G as shown in chemical formula [20] or DCM as shown in the chemical formula [21] etc. Furthermore, a mixture of two or more than two kinds of the above described compounds can be used as the red dopant dye 14c. Preferably, only one of DCJTB and DCM2 is used as the red dopant dye 14c. The total weight content of the yellow dopant dye 14b and the red dopant dye 14c is from 0.1 to 2 weight percent with respect to the hole-transporting compound (the host compound) of the red emitting layer 35. The yellow dopant dye 14b is from 0.5 to 1.5 weight percent (preferably 1 weight percent) and the red dopant dye 14c is from 0.25 to 0.75 weight percent (preferably 0.5 weight percent) with respect to the hole-transporting compound (the host compound) of the red emitting layer 35.

The blue emitting layer 13 contains a blue emitting compound as a host compound and is doped with a blue dopant dye 14a. Namely, the blue emitting layer 13 is formed from the blue emitting compound and the blue dopant dye 14a which is dispersed into the blue emitting compound. The blue emitting compound of the blue emitting layer 13 is an anthracene derivative or a styryl derivative for example. The styryl derivative preferably satisfies the structural formula [10], the same as the first embodiment. The styryl derivative is preferably DPVBi (1,4-bis(2,2-diphenylvinyl)biphenyl) as shown in the structural formula [11] or ADS082 (4,4-Bis(diphenylvinylene)-biphenyl) for example. The anthracene derivative is preferably β-ADN (9,10-di(2-naphthyl)anthracene) as shown in the chemical formula [12] or TBADN (2-t-buthyl-9,10-di(2-naphthyl)anthracene) as shown in the chemical formula [13] for example. In this embodiment, a mixture of two or more than two kinds of the above described compounds can be used as the blue emitting compound, but preferably only DPVBi or ADS082 is used as the blue emitting compound.

The blue dopant dye 14a is a perylene derivative or Pe (perylene) as shown in the chemical formula [14], the same as the first embodiment. The perylene derivative is preferably TBPe (Tetra(t-butyl)perylene) as shown in the structural formula [15], the same as the first embodiment. A mixture of the above compounds can be used as the blue dopant dye 14a.

The thickness of the blue emitting layer 13 is preferably from about 10 nm to about 30 nm, and is more preferably 20 nm. The content of the blue dopant dye 14a is from 2 to 4 weight percent, preferably 3 weight percent, with respect to the blue emitting compound (the host compound) of the blue emitting layer 13. Further, the blue emitting layer 13 does not have to be doped with the blue dopant dye 14a. The green emitting layer 16 contains a green emitting compound, which is preferably an alkylate compound, and which is for example Alq₃ (tris-(8-hydroxy-quinoline)aluminum) as shown in the chemical formula [22]. Of course, the green emitting layer can be formed from other organic compounds. The thickness of the green emitting layer 16 is from about 10 nm to about 30 nm, and preferably is about 20 nm.

As described above, the thickness of the red emitting layer 35 is larger than the thickness of either the green emitting layer 16 or the blue emitting layer 13, and is preferably about twice the thickness of either the blue emitting layer 13 or the green emitting layer 16.

Further, the green emitting layer 16 can contain an organic compound (for example Alq₃) which is doped with a green dopant dye. The green dopant dye is coumarin 6 or C545T (as shown in the chemical formula [23-1] or [23-2], etc.

The anode 11 and the cathode 18, which the organic layer 21 is inserted between, are connected to a battery 22. An electron injection layer 17 is formed between the cathode 18 and the organic layer 21.

When the voltage is applied between the anode 11 and the cathode 18 from the battery 22, the holes are injected from anode 11 and the electrons are injected from the cathode 18. The holes injected from the anode 11 are taken into the red emitting layer 35 by the hole-injection layer 19. The red emitting layer 35 plays the role of the hole-transporting layer, therefore the holes, which are taken into the red emitting layer 35, are transported to the blue and green emitting layers 13, and 16 by the red emitting layer 35. On the other hand, the electrons injected from the cathode 18 are taken by the electron injection layer 17, and then transported to the red, blue, and green emitting layers 35, 13, and 16. The electrons and holes are recombined and then to form excitons in the interface of each captured in each emitting layer 13, 15, and 16.

The energy of the excitons in the red emitting layer 35 is transferred to the yellow dopant dye 14b from NPB (the blue emitting compound), because the energy level in the excited state of the yellow dopant dye 14b is lower than the energy level in the excited state of the blue emitting compound. And then, the energy in the yellow dopant dye 14b is transferred to the red dopant dye 14c, because the energy level in the excited state of the red dopant dye 14c is lower than the energy level in the excited state of the yellow dopant dye 14b. Due to this, red light having high color purity is created in the red emitting layer 35. Blue and green light are respectively created in the blue and green emitting layer 13 and 16 by the excitons. The blue, red, and green light created in each emitting layer mix, hence the EL device 20 emits white light.

As described above, the red emitting layer 35 is doped with not only the red dopant dye 14c but also the yellow dopant dye 14b, therefore the red emitting layer 35 can emit the vivid red light having high color purity. Due to this, the white organic EL device 20 can emit white light having high color purity.

In the fifth embodiment, the red emitting layer 35 is formed from the blue emitting compound (NPB) having great superior hole-transporting properties. Namely, in the fifth embodiment, the organic layer 21 does not need to have the hole-transporting layer; therefore, the white organic EL device can be obtained by a simpler structure. Of course, the hole-transporting layer can be formed between the red emitting layer 35 and the hole-injection layer 19 in a similar way to the first embodiment.

Furthermore, the color balance of the white light created by the white organic EL device 40 is the same, when the applied voltage is changed as described below.

Further, the red emitting layer 35 can be doped with only one of the red dopant dye 14b or the yellow dopant dye 14c. In this case, the content of the red dopant dye 14b or the yellow dopant dye 14c is from 0.5 to 2.0 weight percent with respect to the host compound, and is preferably 1 weight percent.

Of course, compounds other than the above-described compounds can be used as the compound of each layer composing the white organic EL device in the above embodiments.

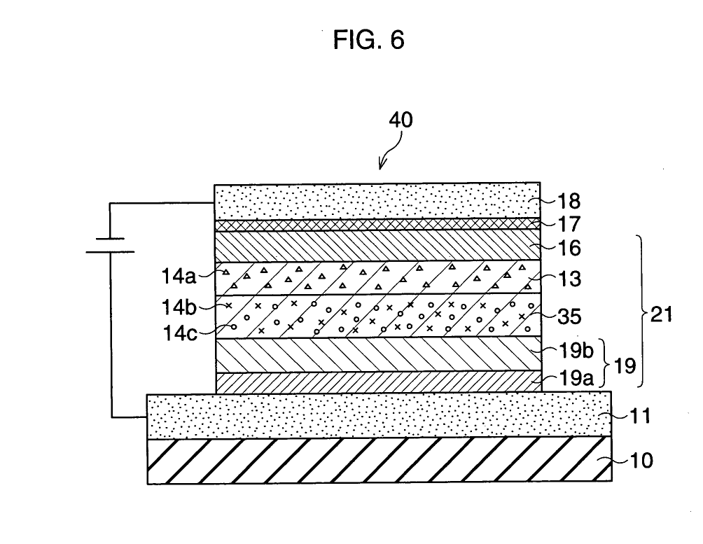

FIG. 6 shows a white organic EL device of the sixth embodiment. The EL device 40 of the sixth embodiment has the same structure as that of the fifth embodiment except for the hole-injection layer 19. Therefore, the organic layer 21 of the sixth embodiment has the same structure as that of the fifth embodiment except for the hole-injection layer 19.

In the sixth embodiment, the hole-injection layer (the hole-buffer layer) 19 consists of the first hole-injection layer 19a and the second hole-injection layer 19b. The first hole-injection layer 19a and the second hole-injection layer 19b are laid in sequence from the anode 11 side. The first hole-injection layer 19a contains CuPc as shown in chemical formula [4-2] and the second hole-injection layer 19b contains MTDATA as shown in chemical formula [4].

The thickness of the second hole-injection layer 19b is larger than the thickness of the first hole-injection layer 19a, and is from about 12 nm to about 18 nm. The thickness of the first hole-injection layer 19a is from about 2 nm to about 8 nm.

In the sixth embodiment, due to forming the hole-injection layer 19 from CuPc and MTDATA, the holes which are injected in the emitting layers 35, 13, and 16 can be decreased. Therefore, in each emitting layer, the number of the holes is balanced with the number of the electrons and then the luminous efficiency of the EL device 40 can be improved.

In the sixth embodiment, if only the hole-injection layer 19 is formed by CuPc and MTDATA, the hole-injection layer 19 can consist of the single layer similar to the fifth embodiment. Namely the hole-injection layer l9 can be formed from a mixture of CuPc and MTDATA. In this case, the weight ratio between the CuPc and MTDATA is in the range from 1:1 to 1.5:1, for example, and the thickness of the hole-injection layer 19 is from about 10 nm to about 80 nm similar to the fifth embodiment.

Further, the structure of the organic layer 21 except for the hole-injection layer 19 is not limit to the structure as described above, and can be formed using a structure other than the structure described above.

In the first to sixth embodiments, the base member 10 is formed on the anode 11 side in the above embodiments as described above. Also, the base member 10 can be formed on the cathode 18 side in the above embodiments. Furthermore, the cathode 18 can be formed of a light permeable compound, and the white light can be sent through the cathode 18. Further, the base member 10 can be formed of other materials besides glass, for example resin.

### EXAMPLES

The present invention will be explained with reference to examples of the invention as well as comparative examples. Note that the present invention is not limited in any way by these examples.

### Example 1

Example 1 corresponds to the first embodiment. However, in Example 1, the organic layer 21 did not have the hole-injection layer 19 and the electron-transporting layer 25. Further, the red emitting layer 15 was doped with only the red dopant dye 14c, and the blue emitting layer 13 was not doped with the blue dopant dye 14a. Namely, the white organic EL device of Example 1 was made as described below. At first, a glass plate which could transmit light was prepared as base member 10, and ITO was vapor deposited on the glass plate so that the anode 11 having a thickness of 100 nm was formed. Next, NPB as shown in the chemical formula [8] was vapor deposited on the anode 11 so that the hole-transporting layer 12 having a thickness of 90 nm was formed. ADS082 (4,4-Bis(diphenylvinylene)-biphenyl) namely the blue emitting compound was vapor deposited on the hole-transporting layer 12 so that the blue emitting layer 13 having a thickness of 20 nm was formed. Next, ADS082 and DCJTB as shown in the chemical formula [19] were vapor deposited on the blue emitting layer 13 at the same time, so that the red emitting layer 15 having a thickness of 10 nm was formed. Alq₃ as shown in the chemical formula [22] was vapor deposited on the red emitting layer 15 so that the green emitting layer 16 having a thickness of 25 nm was formed. Next LiF was vapor deposited on the green emitting layer 16 so that the electron injection layer 17 having a thickness of 0.7 nm was formed. Aluminum was vapor deposited on the electron injection layer 17 so that the cathode 18 was formed, and due to the above process the white organic EL device 20 was obtained. Further, the vapor depositions were vacuum deposition of PVD in Example 1.

### Example 2

Example 2 corresponds to the second embodiment. Example 2 had the same structure as that of Example 1 except that the layer sequence of the blue emitting layer 13 and the red emitting layer 15 was reversed. Namely, the red emitting layer 15, the blue emitting layer 13, and green emitting layer 16 were laid in sequence from the anode 11 side in the white organic EL device 20 of Example 2.

### Example 3

Example 3 corresponds to the second embodiment. Example 3 had the same structure as that of Example 2 except for the thickness of the hole-transporting layer 12. In Example 3, the thickness of the hole-transporting layer 12 was 40 nm.

### Example 4

Example 4 corresponds to the third embodiment. In the Example 4, the organic layer 21 did not have the hole-injection layer 19 and the electron-transporting layer 25, the red emitting layer 15 was doped with only the red dopant dye 14c, and the first and second blue emitting layers 13a and 13b were not doped with the blue dopant dye 14a.

Namely, the white organic EL device of Example 4 was produced as described below. At first the base member 10, anode 11, and the hole-transporting layer 12 were formed in the same way as in Example 1. Next, the first blue emitting layer 13a having a thickness of 5 nm was formed by ADS082 on the hole-transporting layer 12. Next, the red emitting layer 15 having a thickness of 10 nm was formed by ADS082 and DCJTB as shown in the chemical formula [19] on the first blue emitting layer 13a. The second blue emitting layer 13b having a thickness of 15 nm was formed by ADS082 on the red emitting layer 15. The green emitting layer 16, the electron injection layer 17, and the cathode 18 were formed on the second blue layer 13b in the same way as in Example 1, and due to the above processes the white organic EL device 20 was obtained.

### Examples 5-6

Examples 5 and 6 correspond to the third embodiment. Examples 5 and 6 had the same structure as that of Example 4 except for the thickness of the first and second blue emitting layers 13a and 13b, and the red emitting layer 15.

Namely, the thicknesses of the first blue emitting layer 13a, the red emitting layer 15, and the second blue emitting layer 13b were 10 nm, 10 nm, and 10 nm respectively in Example 5.

In Example 6, the thicknesses of the first blue emitting layer 13a, the red emitting layer 15, and the second blue emitting layer 13b were 15 nm, 10 nm, and 5 nm respectively.

### Example 7

Example 7 corresponds to the fourth embodiment. However, in Example 7 the organic layer 21 did not have the hole-injection layer 19 and the electron-transporting layer 25, the red emitting layer 15 was doped with only the red dopant dye 14c, and the first and second blue emitting layers 13a and 13b were not doped with the blue dopant dye 14a.

Namely, the white organic EL device of Example 7 was produced as described below. At first the base member 10, anode 11, and the hole-transporting layer 12 were formed in same way as in Example 1. Next, the first blue emitting layer 13a having a thickness of 10 nm was formed by ADS082 on the hole-transporting layer 12. The second green emitting layer 16b having a thickness of 5 nm was formed by ADS082 and coumarin 6 on the first blue emitting layer 13a. The red emitting layer 15 having a thickness of 5 nm was formed by ADS082 and DCJTB on the second green emitting layer 16b. Next, the second blue emitting layer 13b having a thickness of 10 nm was formed by ADS082 on the red emitting layer 15. Next, the first green layer 16a having a thickness of 25 nm was formed by Alq₃ on the second blue emitting layer 13b. And then, the electron injection layer 17 and the cathode 18 were formed on the first green layer 16a in the same way as in Example 1, and due to above process the white organic EL device 20 was obtained.

### Example 8

Examples 8 correspond to the fourth embodiment. Example 8 had the same structure as that of Example 7 except that the thicknesses and layer sequence of the first blue emitting layer 13a, the second green emitting layer 16b, and the red emitting layer 15 were changed.

In Example 8, the first blue emitting layer 13a having a thickness of 5 nm, the red emitting layer 15 having a thickness of 5 nm, the second green emitting layer 16b having a thickness of 5 nm, and the second blue layer emitting layer 13b having a thickness of 10 nm were laid in sequence on the hole-transporting layer 12.

### Example 9

Example 9 had the same structure as that of Example 6 except for the hole-transporting layer 12 and the green emitting layer 16. Namely, in Example 9 the hole-transporting layer 12 having a thickness of 40 nm was formed by TPD as shown in the chemical formula [9]. Further, a thickness of the green emitting layer 16 was 20 nm.

Furthermore, the content of the red dopant dye 14c was 2 weight percent with respect to the blue emitting compound (the host compound) which formed the red emitting layer 15, in Examples 1 to 9. On the other hand, the content of the green dopant dye 14d was 1 weight percent with respect to the blue emitting compound (the host compound) which formed the first green emitting layer 16a.

### Example 10

Example 10 corresponds to the fifth embodiment. The white organic EL device 40 of Example 10 had the red emitting layer doped with both yellow dopant dye 14b and red dopant dye 14c.

Namely, the white organic EL device of Example 10 was produced as described below. At first base member 10 and the anode 11 were formed in the same way as in Example 1. Next, the hole-injection layer 19 having a thickness of 60 nm was formed by MTDATA. The red emitting layer 35 having a thickness of 40 nm was formed by NPB, Rubrene, and DCJTB on the hole-injection layer 19. The blue emitting layer 13 having a thickness of 20 nm was formed by DPVBi and TPBe on the red emitting layer 35. Next, the green emitting layer 16 having a thickness of 20 nm was formed by Alq₃ on the blue emitting layer 13. The electron injection layer 17 and the cathode 18 were formed in sequence on the green emitting layer 16 in the same way as in Example 1, and due to the above processes the white organic EL device 40 was obtained.

In Example 10, the content of TBPe was 3 weight percent with respect to DPVBi (the blue emitting compound) which formed the blue emitting layer 13. Further, the content of Rubrene and DCJTB were 1 weight percent and 0.5 weight percent respectively with respect to NPB (the blue emitting compound) which formed the red emitting layer 35.

### Example 11

Example 11 had the same structure as that of Example 10 except that the red emitting layer 35 was doped with only the yellow dopant dye 14b. Namely, the red emitting layer 35 was formed by NPB and Rubrene. The content of the Rubrene was 1 weight percent with respect to NPB (the blue emitting compound) which formed the red emitting layer 35.

### Example 12

Example 12 had the same structure as that of the Example 11 except for the content of Rubrene and the thickness of the layers. Namely, the contents of Rubrene was 2 weight percent with respect to NPB (the blue emitting compound) which formed the red emitting layer 35 in Example 12. Further, the thicknesses of the hole-injection layer 19, the red emitting layer 35, the blue emitting layer 13, and the green emitting layer 16 were 30 nm, 40 nm, 20 nm, and 20 nm respectively.

### Example 13

Example 13 had the same structure as that of the Example 12 except for the hole-injection layer 19. The hole-injection layer 19 was formed by MTDATA as shown in chemical formula [4] in Example 12, but in Example 13 it was formed by CuPc as shown in chemical formula [4-2].

### Example 14

Example 14 corresponds to the sixth embodiment. Example 14 had the same structure as that of Example 12 except for the hole-injection layer 19. The hole-injection layer 19 was formed by the mixture of MTDATA and CuPc in Example 14. The weight ratio between MTDATA and CuPc was 1.2:1. Further, MTDATA and CuPc were vapor deposited at the same time in order to form the hole-injection layer in Examle 14.

### Example 15

Example 15 corresponds to the sixth embodiment. Example 15 had the same structure as that of Example 11 except for the hole-injection layer 19 and the content of the Rubrene. In Example 15, the hole-injection layer 19 had the first hole-injection layer 19a and the hole-injection layer 19b in sequence from the anode 11. The first hole-injection layer 19a was formed by CuPc and the second hole-injection layer 19b was formed by MTDATA. The first hole-injection layer 19a and the second hole-injection layer 19b had thickness of 5 nm and 15 nm respectively. Further, the content of the Rubrene was 2 weight percent with respect to NPB (the blue emitting compound) which formed the red emitting layer 35.

### Comparative Example 1

The white organic EL device of Comparative example 1 was produced as described below to show the effect of the Examples. At first base member 10, the anode 11, and the hole-injection layer 19 were formed in the same way as in Example 10. Next, the hole-transporting layer having a thickness of 20 nm was formed by NPB on the hole-injection layer. Then, the blue emitting layer having a thickness of 10 nm was formed by DPVBi and TBPe on the hole-transporting layer. Then, the red emitting layer having a thickness of 10 nm was formed by Rubrene and Alq₃ on the blue emitting layer. After this, the green emitting layer having a thickness of 20 nm was formed by Alq₃ on the red emitting layer. The electron injection layer and the cathode were formed on the green emitting layer in the same way as in Example 1, and due to the above processes the white organic EL device of the Comparative example 1 was obtained.

In Comparative example 1, the content of TBPe was 3 weight percent with respect to DPVBi (the blue emitting compound) which formed the blue emitting layer. Further, the content of Rubrene was 1 weight percent with respect to Alq₃ (the green emitting compound) which formed the red emitting layer.

Further each layer of the EL device of Examples 2-14, and Comparative example 1 was formed by vapor deposition in the same way as in Example 1.

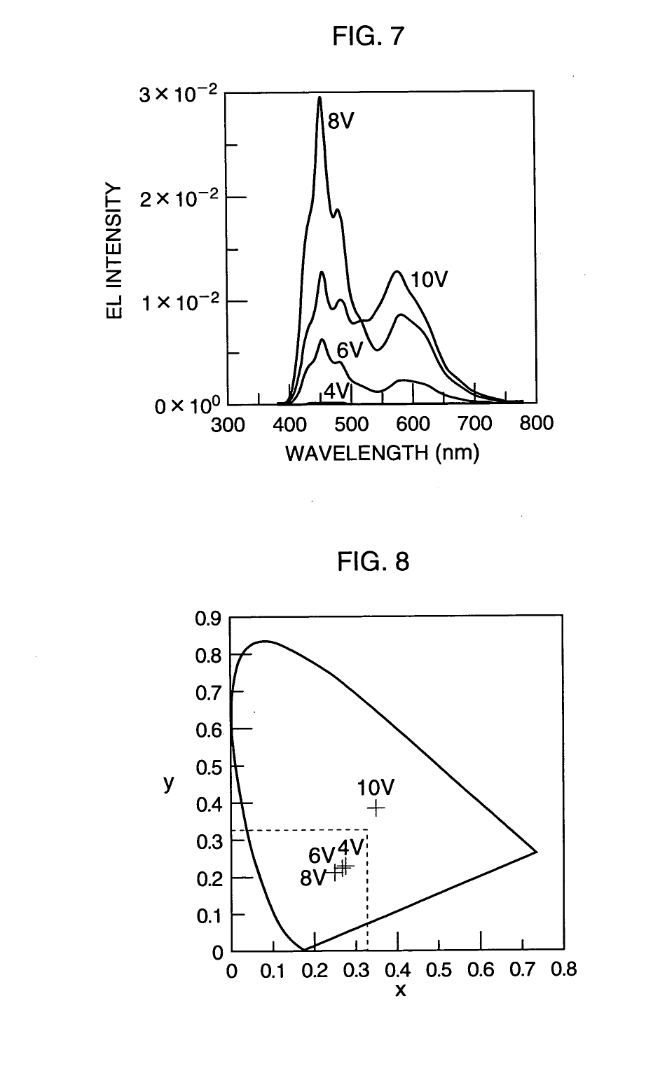

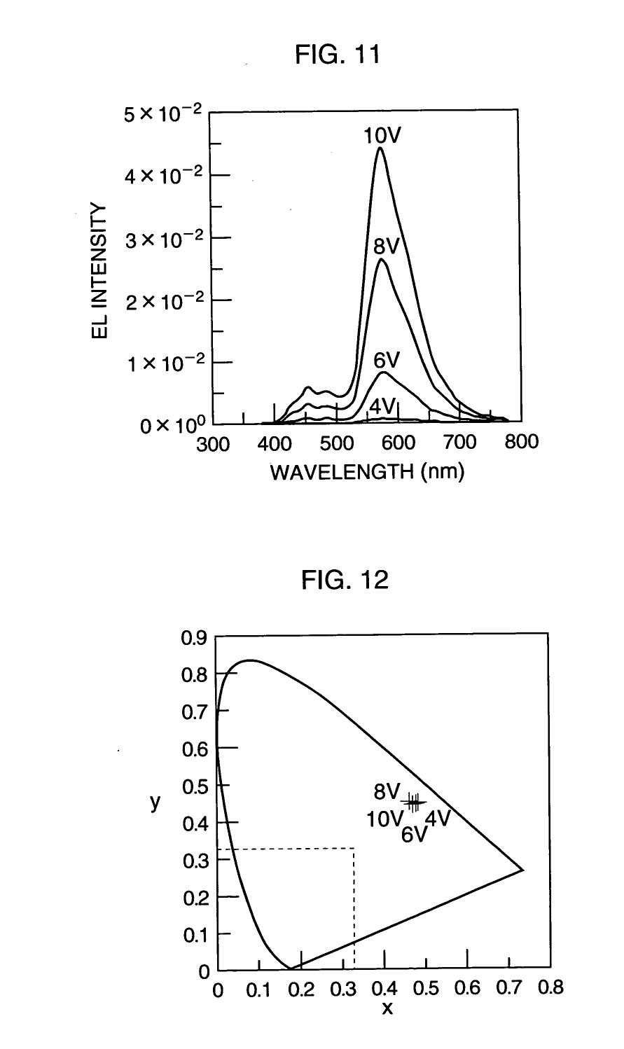

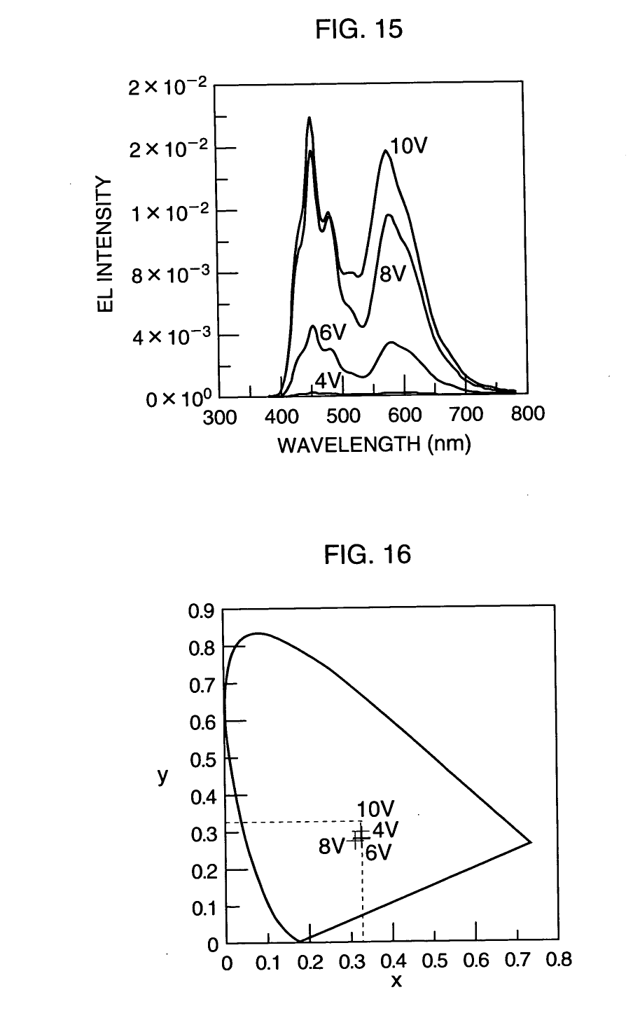

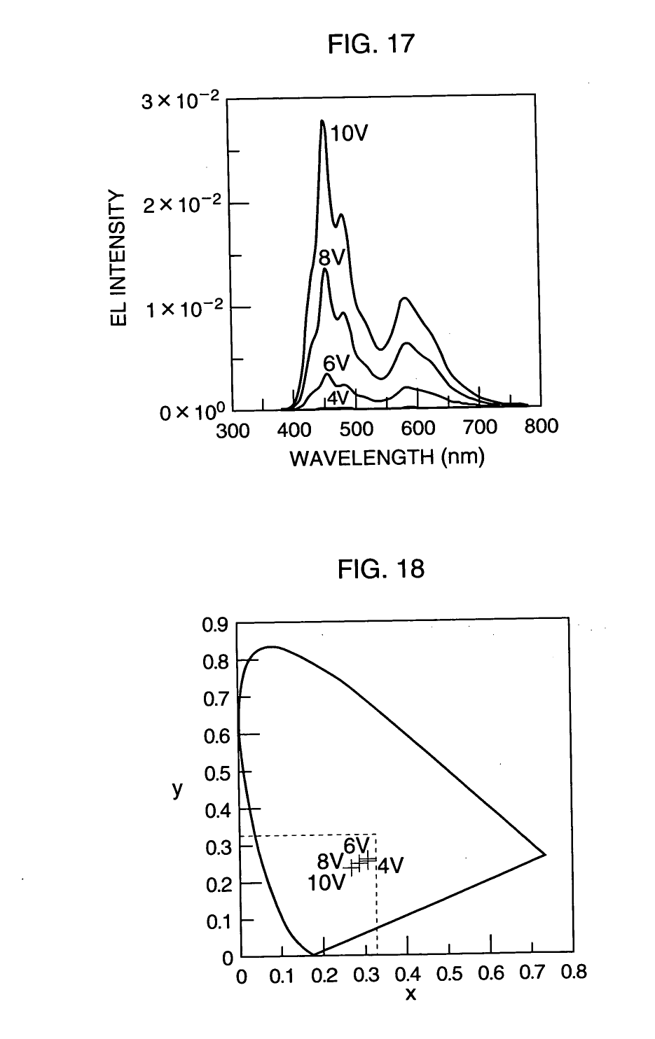

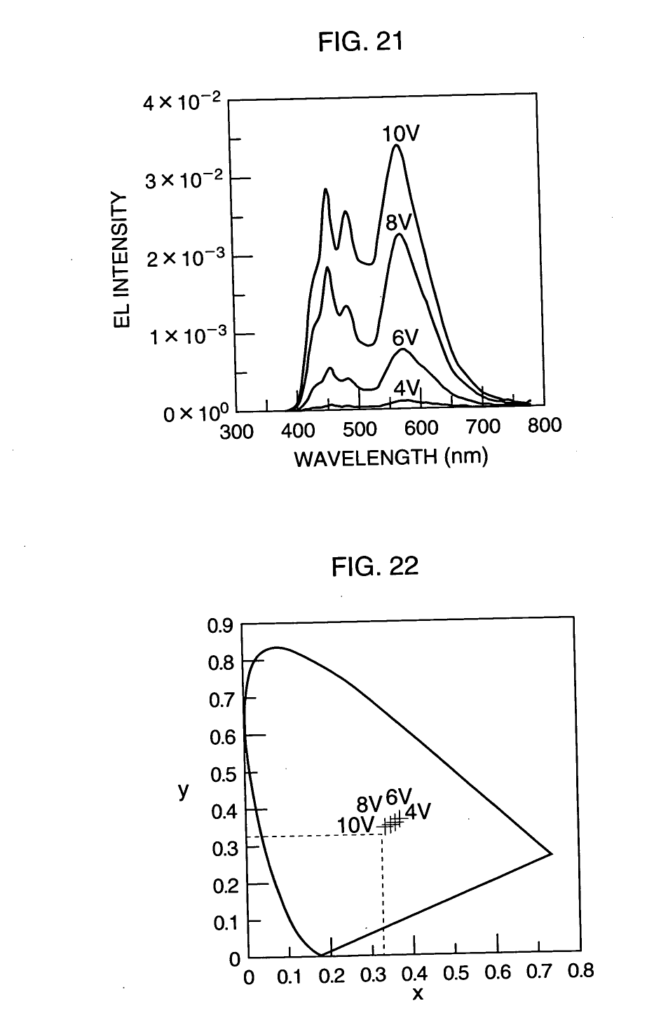

FIGS. 7-24 show EL (electroluminescence) spectrums and chromaticity coordinates of Examples 1-9, when the applied voltages were 4, 6, 8, and 10V.

As shown in FIG. 8, the white organic EL device in Example 1 emitted almost white light (except for when the applied voltage was 10V). The difference in the chromaticity was small when the applied voltage changed in the range form 4V to 8V.

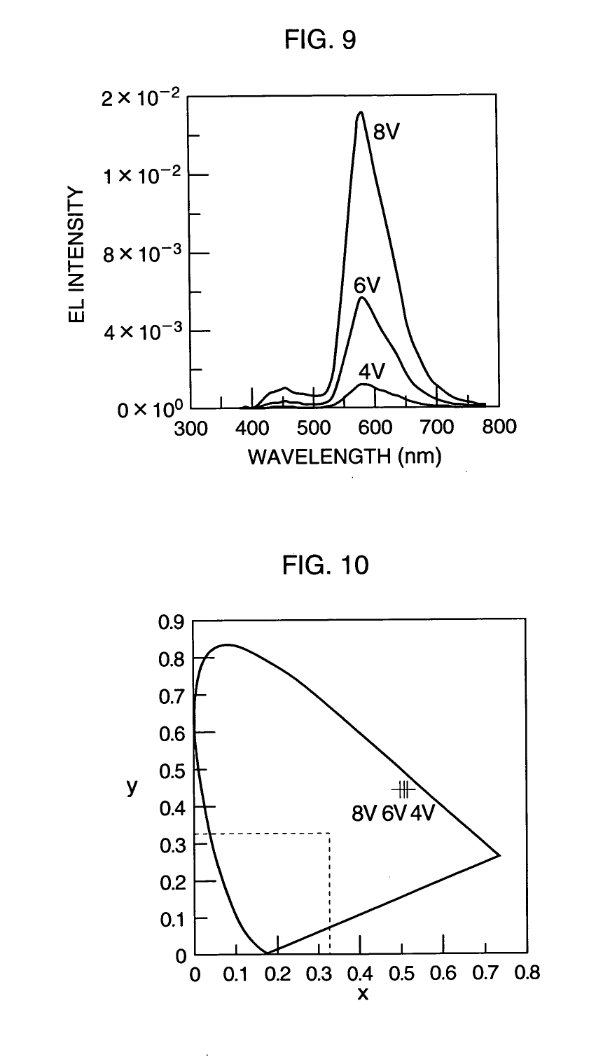

As shown in FIGS. 9-12, the differences of the chromaticity were small when the applied voltages changed in the range from 4V to 10V in Example 2 and 3. However, the light, which the white organic EL devices of Examples 2 and 3 emitted, approached yellow, as the chromaticity coordinates show.

As shown in FIGS. 7-12, the color balances of the lights which the white organic EL devices emit did not change, when the applied voltage was changed in the first and second embodiments. Further, the highly pure white colors were obtained, when the blue emitting layer, the red emitting layer, and the green emitting layer, were laid in sequence from the anode side.

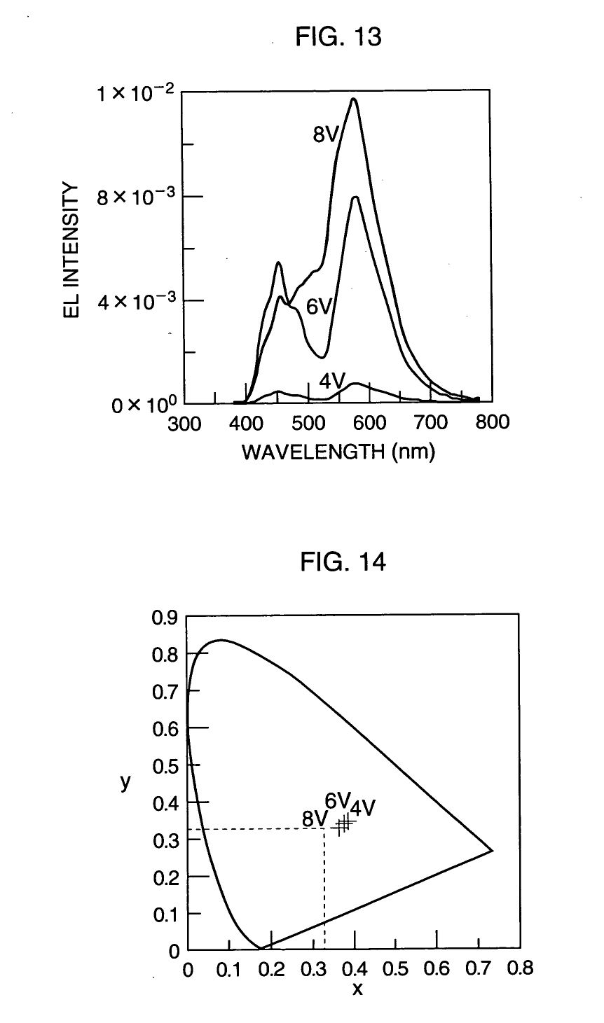

FIGS. 13-18 show the EL spectrums and the chromaticity coordinates of Examples 4, 5, and 6 respectively. The white organic EL devices also emitted almost white light when the devices had two blue emitting layers, as can be seen from the results of Examples 4, 5, and 6. Further, the chromaticity did not change in Examples 4, 5, and 6, when the applied voltages changed, which was similar to Examples 1, 2, and 3.

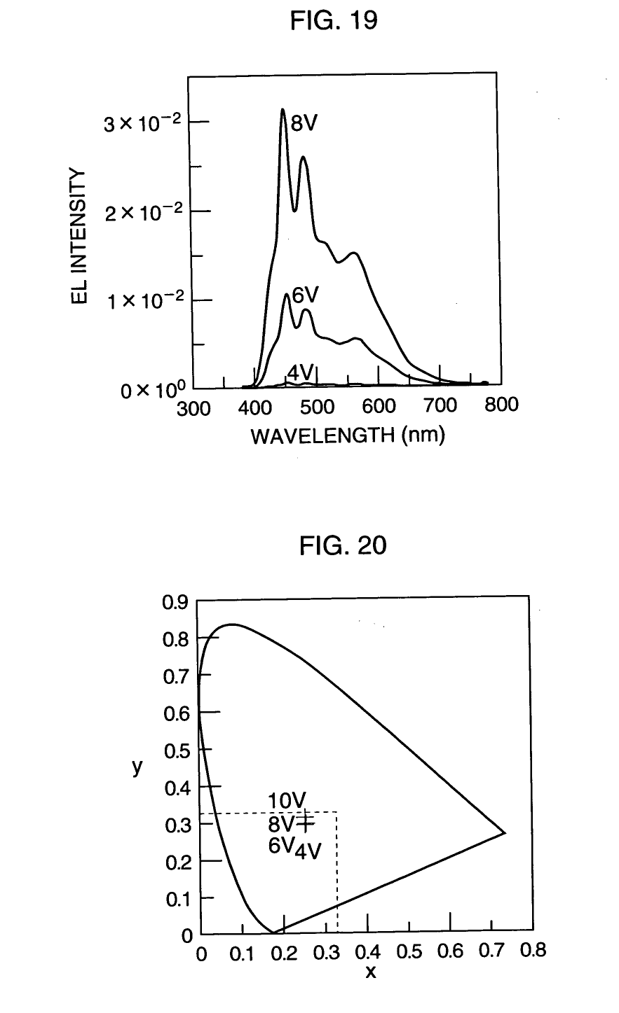

FIGS. 19-22 show the EL spectrums and the chromaticity coordinates of Examples 7 and 8 respectively. The white organic EL devices emitted almost white light when the devices had the green emitting layer between the two blue emitting layers as can be seen from the results of Examples 7 and 8. The chromaticity did not change in Examples 7 and 8, when the applied voltage changed, which was similar to Examples 1-6.

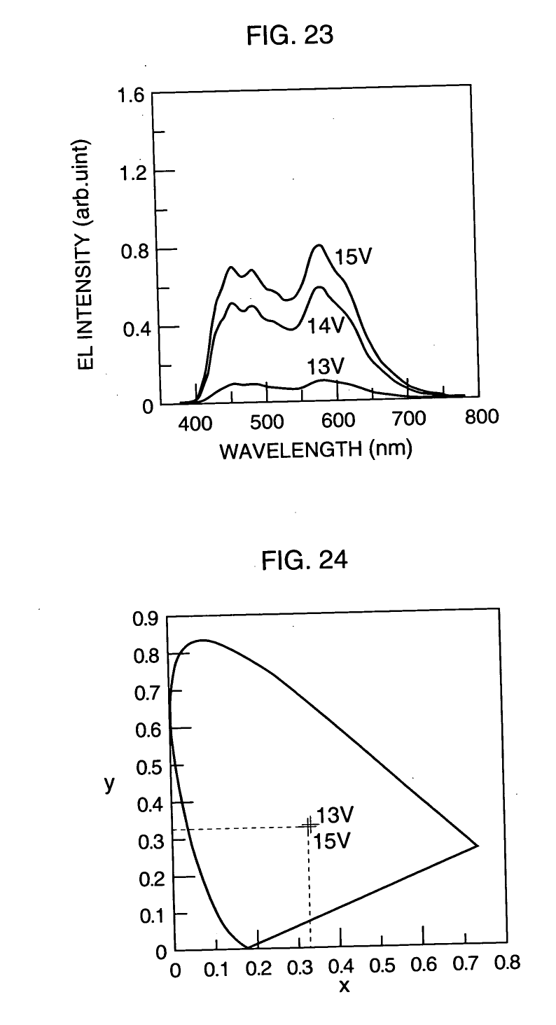

FIGS. 23 and 24 show the EL spectrums and the chromaticity coordinates of Example 9. The white organic EL devices emitted white light of which the color balance did not change depending on the applied voltage, when the hole-transporting layer was changed from NPB to TPD.

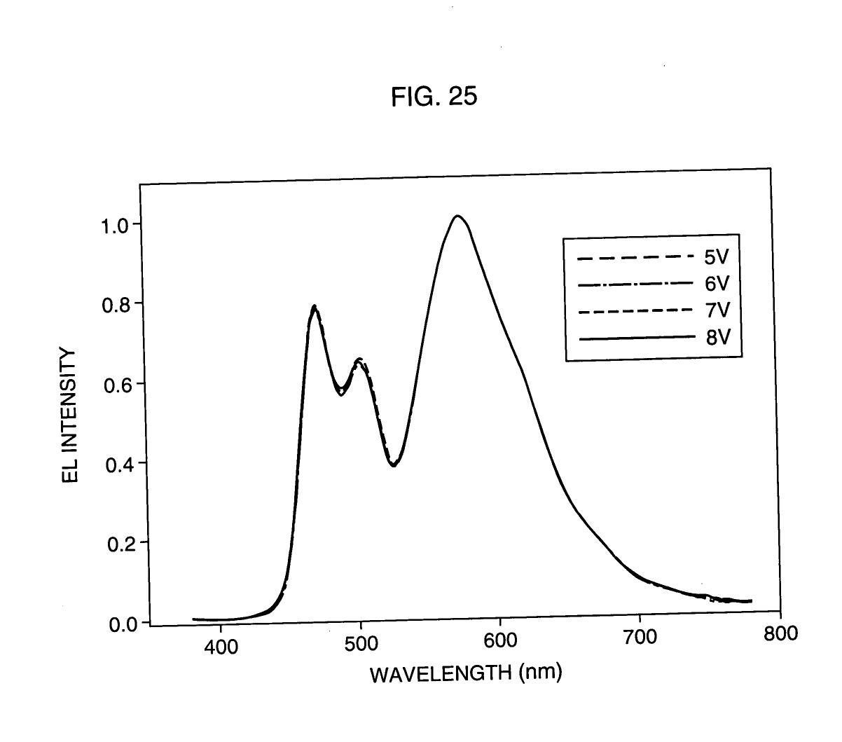

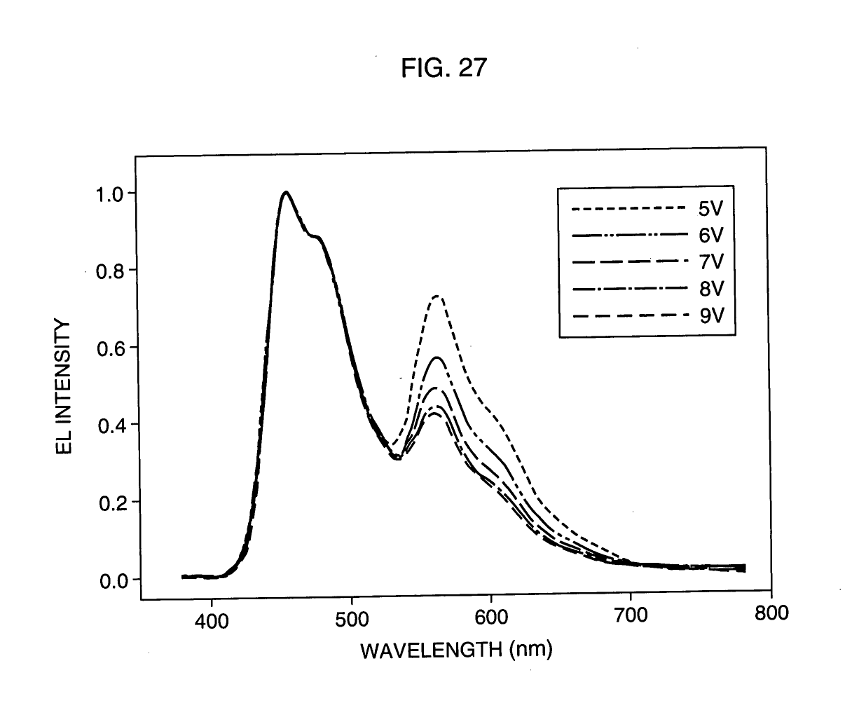

FIGS. 25, 26, and 27 show the EL spectrums of Examples 10 and 11, and Comparative example 1, when the applied voltage was changed in the range from 4 V to 9V. The EL spectrums in FIGS. 25, 26, and 27 were normalized spectrums. The EL intensity of the highest wave peak in the spectrum measured for each voltage (4-9V) was adjusted to 1.0, so that the normalized spectrum was obtained.

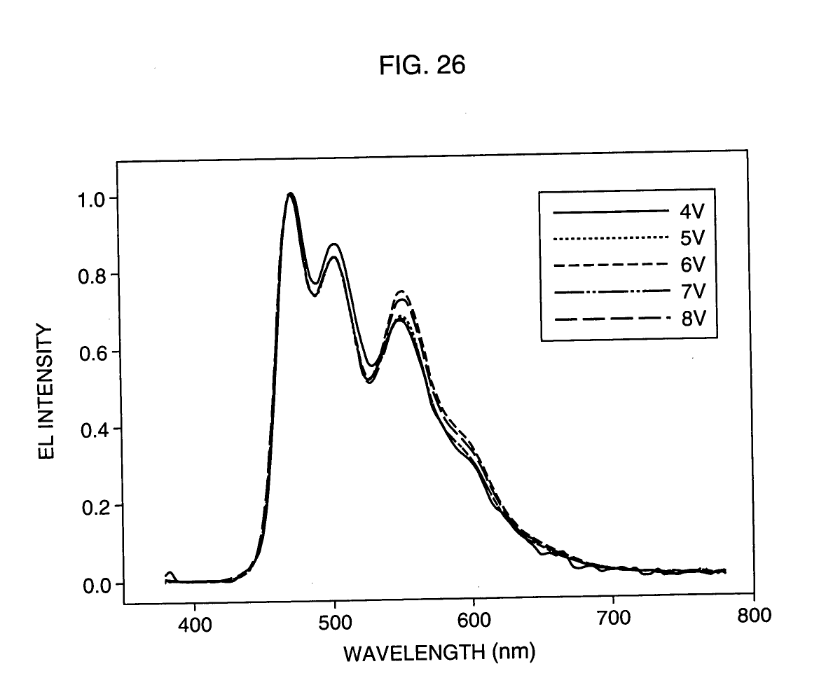

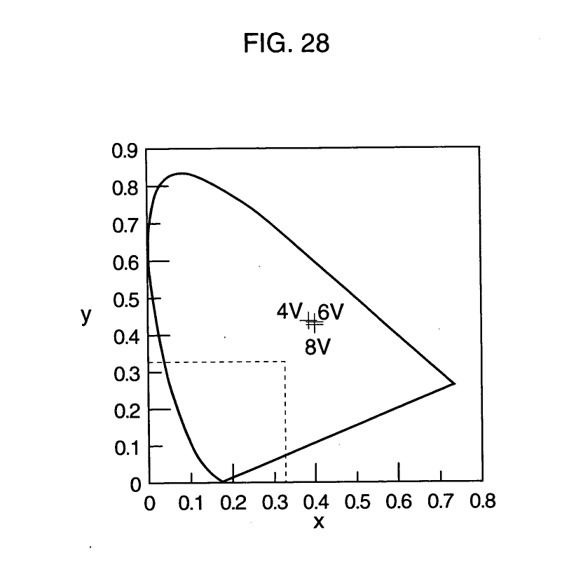

As shown in FIGS. 25 and 26, the normalized spectrums were almost the same as those in Examples 10 and 11, when the applied voltage was changed from 4V to 8V. Namely, the color balances in Examples 10 and 11 did not change, when the applied voltage was changed. Further, the chromaticity coordinate in FIG. 28 shows the relation between the applied voltages and the chromaticity in Example 10, so the color balances in Example 10 did not change depending on the applied voltage also as this figure.

On the other hand, the EL intensity of the peak around 580 nm in the normalized spectrums of Comparative example 1 dropped as the applied voltage increased. Namely, when the applied voltage was increased from 5V to 9V, the intensity of the yellow and red light decreased and the color balance of the light which the EL device emitted changed in Comparative example 1.

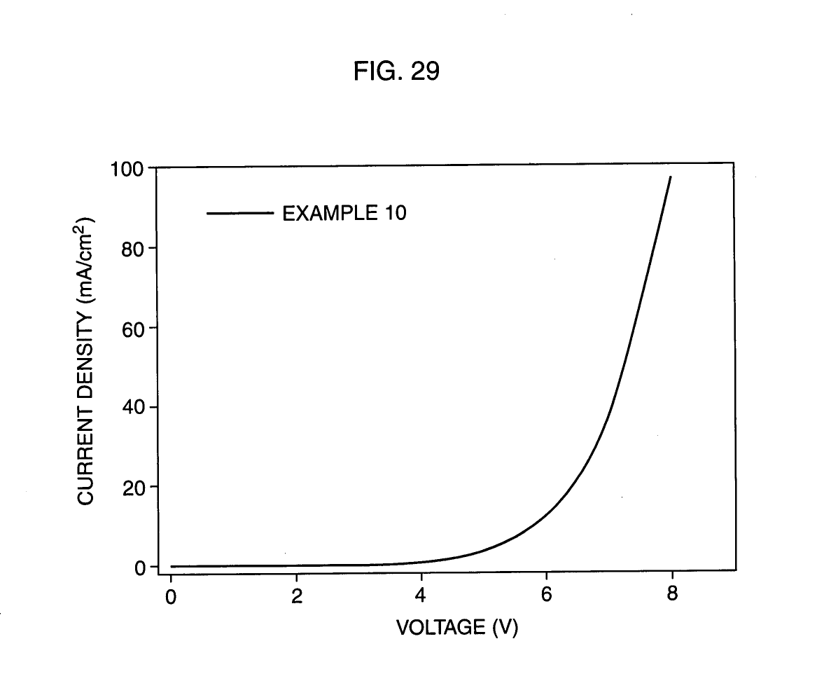

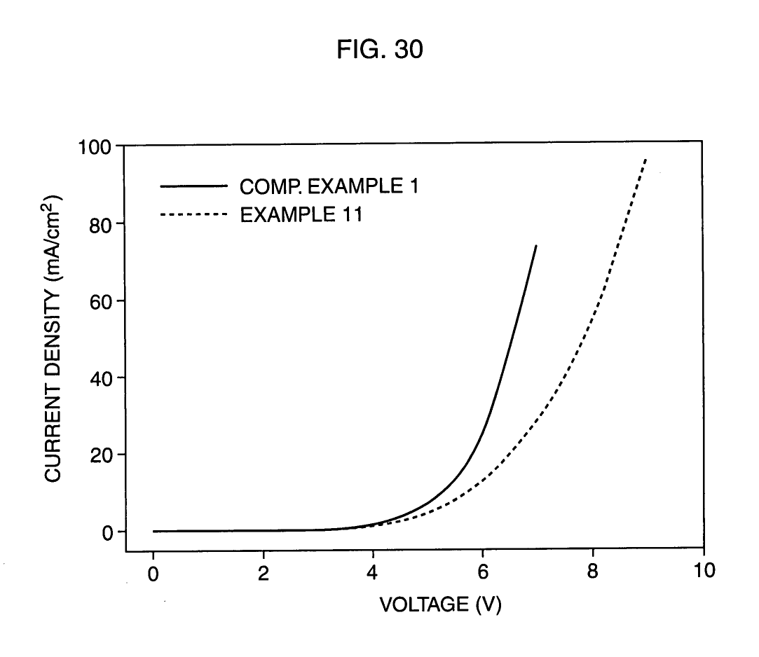

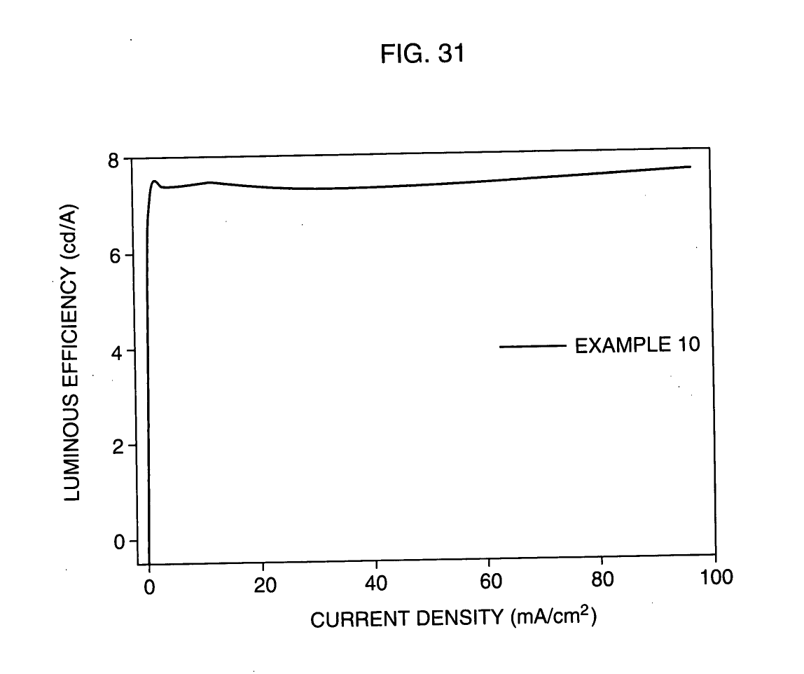

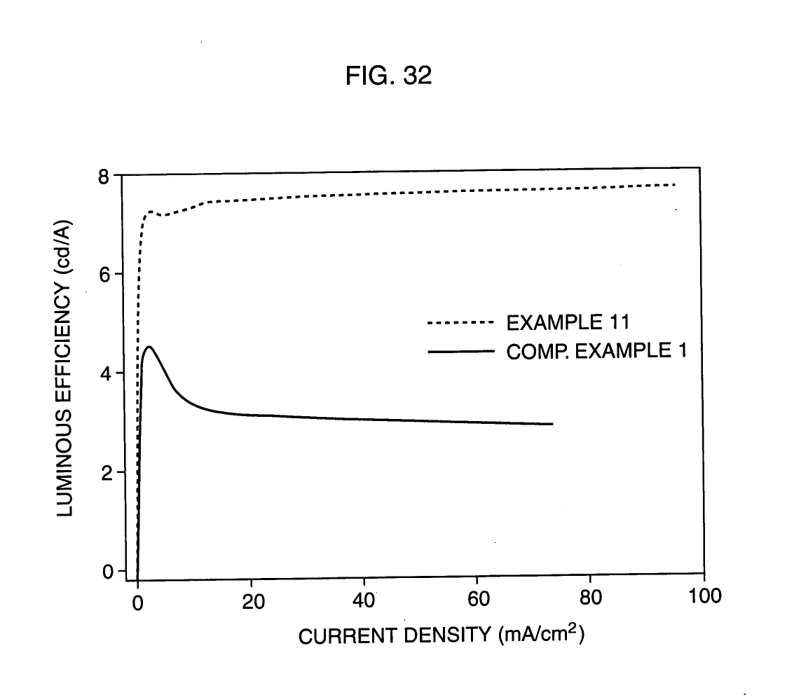

FIGS. 29 and 30 show the relation between the applied voltage to the anode and the cathode, and the current density in Example 10 and 11 and Comparative example 1. FIGS. 31 and 32 show the relation between the current density and the luminous efficiency. The luminous efficiency of the EL device of Examples 1 and 2 was much better than that of Comparative example 1 as shown in FIGS. 31 and 32. Further, the luminance of the EL device of Example 10, which was measured at voltages 4, 6, and 8 V, was 31, 886, and 7352 cd/m² respectively. So the EL device of the fifth embodiment emitted high luminance light at high voltages.

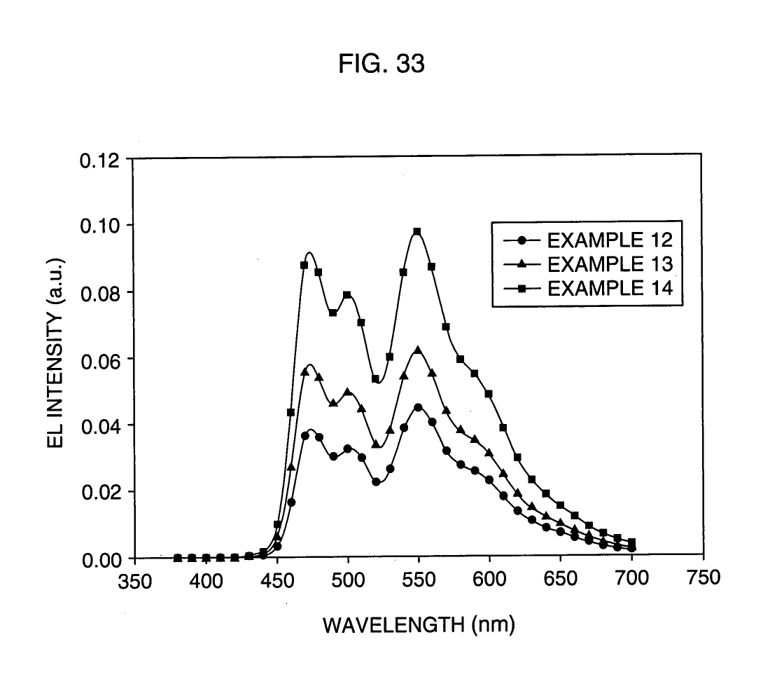

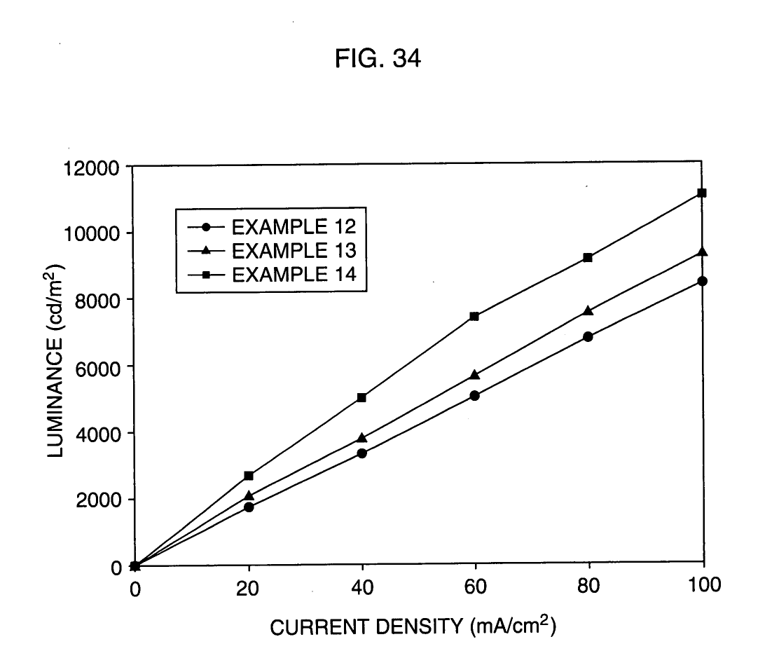

FIG. 33 shows the electroluminescence (EL) spectrums in Examples 12-14, when the same voltage 9 V was applied to the EL device. FIG. 34 shows the relation between the current density and the luminance in Examples 12-14.

As shown in FIGS. 33 and 34, when CuPc was used for the hole-injection layer 19 the luminous efficiency was better than when MTDATA was used for the same purpose. Further, it was surprising that the luminous efficiency was greatly improved when the mixture of CuPc and MTDATA was used as the hole-injection layer 19.

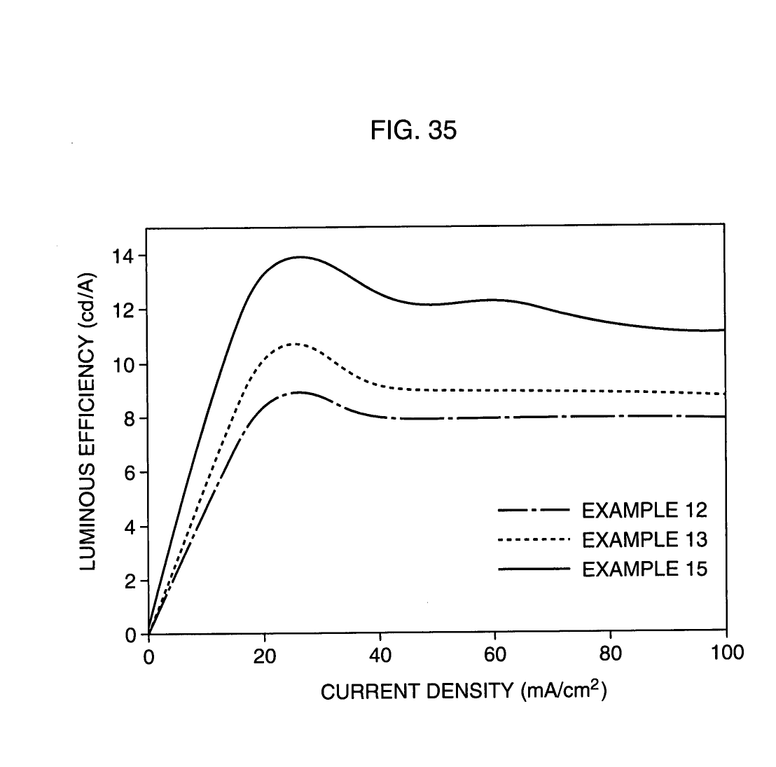

FIG. 35 shows the relation between the current density and the luminous efficiency in Examples 12, 13, and 15. As shown in FIG. 35, the luminous efficiency was greatly improved when the hole-injection layer 19 consisted of the CuPc layer and the MTDATA layer compared with that when the hole-injection layer 19 consisted of only CuPc or MTDATA.

Although the embodiments of the present invention have been described herein with reference to the accompanying drawings, obviously many modifications and changes can be made by those skilled in this art without departing from the scope of the invention.

The present disclosure relates to subject matter contained in Japanese Patent Applications No. 2003-364482 (filed on Oct. 24, 2003) and No. 2004-188445 (filed on Jun. 25, 2004) which are expressly incorporated herein, by references, in their entirety.

1. An organic electroluminescent device, emitting white light, comprising:
an organic layer between an anode and a cathode on a substrate,
said organic layer having at least;
a first blue emitting layer emitting blue light,
a first green emitting layer emitting green light, and
a red emitting layer emitting red light, containing a blue emitting compound doped with at least one of a yellow dopant dye and a red dopant dye.

2. A device according to claim 1, wherein said blue emitting compound is a hole-transporting compound.

3. A device according to claim 2, wherein said hole-transporting compound satisfies the structural formula 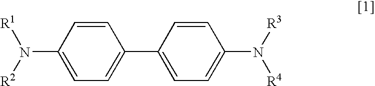
[1]; further R¹, R², R³, and R⁴ in the formula are aryl groups.

4. A device according to claim 3, wherein said hole-transporting compound is NPB.

5. A device according to claim 1, wherein said organic layer has in sequence from said anode, said red emitting layer, said first blue emitting layer, and said first green emitting layer.

6. A device according to claim 1, wherein said red emitting layer contains said red dopant dye, and said red dopant dye satisfies the structural formula [2]; 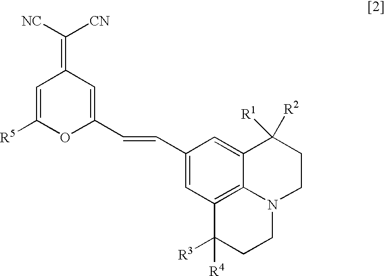
further R¹, R², R³, R⁴, and R⁵ in the formula are hydrogen atoms or alkyl groups having from 1 to 6 carbon atoms.

7. A device according to claim 1, wherein said red emitting layer contains both said yellow dopant dye and said red dopant dye.

8. A device according to claim 7, wherein the content of said yellow dopant dye is higher than the content of said red dopant dye.

9. A device according to claim 8, wherein the weight ratio between said yellow dopant dye and said red dopant dye is in the range from 1.8:1 to 2.2:1.

10. A device according to claim 7, wherein the total weight of yellow dopant dye and said red dopant dye is not more than 2 weight percent with respect to the weight of said blue emitting compound.

11. A device according to claim 1, wherein said first blue emitting layer contains a blue dopant dye.

12. A device according to claim 1, wherein said blue emitting compound satisfies the structural formula [3]; 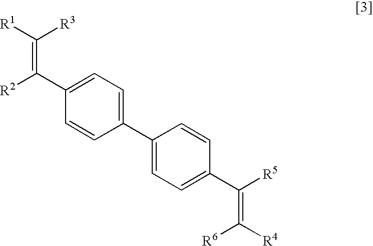
further, R¹, R², R³, R⁴, R⁵ and R⁶ in the formula are hydrogen atoms or aryl groups; at least one of R¹, R², and R³ is an aryl group and at least one of R⁴, R⁵ and R⁶ is an aryl group.

13. A device according to claim 1, wherein said organic layer has in sequence from said anode side said first blue emitting layer, said red emitting layer, and said first green emitting layer.

14. A device according to claim 13, wherein said organic layer has a second blue emitting layer between said red emitting layer and said first green emitting layer.

15. A device according to claim 14, wherein said organic layer has a second green emitting layer on said anode side of said second blue emitting layer.

16. A device according to claim 1, wherein said organic layer has a hole-injection layer on the closest side to said anode, said hole-injection layer containing CuPc and MTDATA.

17. An organic electroluminescent device, for emitting light, comprising:
an organic layer emitting said light between an anode and a cathode on a substrate, said organic layer having a hole-injection layer on the closest side to said anode, said hole-injection layer containing CuPc and MTDATA.

18. A device according to claim 17, wherein said hole-injection layer has a first hole-injection layer containing CuPc and a second hole-injection layer containing MTDATA.

19. A device according to claim 17, wherein said hole-injection layer contains a mixture of CuPc and MTDATA.
